(19) United States
(12) Patent Application Publication
(10) Pub. No.: US 2013/0134507 A1
(43) Pub. Date: May 30, 2013

(54) SEMICONDUCTOR DEVICE INCLUDING SHARED PILLAR LOWER DIFFUSION LAYER

(71) Applicant: Elpida Memory, Inc., Tokyo (JP)

(72) Inventor: Yoshihiro TAKAISHI, Tokyo (JP)

(73) Assignee: ELPIDA MEMORY, INC., Tokyo (JP)

(21) Appl. No.: 13/683,191

(22) Filed: Nov. 21, 2012

(30) Foreign Application Priority Data
Nov. 24, 2011 (JP) 2011-255760

(51) Int. Cl. H01L 29/78; H01L 27/088

(52) U.S. Cl. CPC H01L 29/7827; H01L 27/088
USPC 257/334

(57) ABSTRACT

A semiconductor device includes a high-breakdown voltage transistor in which at least first and second vertical transistor are connected in series to each other. The first vertical transistor includes a first unit transistor group having a plurality of unit transistors each having a semiconductor pillar. The second vertical transistor includes a second unit transistor group having a plurality of unit transistors each having a semiconductor pillar. The plurality of unit transistors constituting the first and the second unit transistor groups have pillar lower diffusion layers which are shared.

This application is based upon and claims the benefit of priority from Japanese patent application No. 2011-255760, filed on Nov. 24, 2011, the disclosure of which is incorporated herein in its entirety by reference.

### BACKGROUND OF THE INVENTION

1. Field of the Invention

This invention relates to a semiconductor device, and in particular to a semiconductor device comprising vertical transistors.

2. Description of Related Art

To take measures against finer design rules of transistors, a three-dimensional transistor having a vertical surround gate transistor (SGT) structure is known. The three-dimensional transistor is a transistor which uses, as a channel, a silicon pillar (a semiconductor pillar) extending along a direction (a Z direction) orthogonal to the principal plane (a XY plane defined by an X direction and a Y direction) of a semiconductor substrate. Herein, such as a three-dimensional transistor is simply referred to as a vertical transistor.

Various transistor devices each having such as a vertical transistor (the vertical SGT structure have been proposed heretofore.

By way of illustration, JP-A-2009-081389 (which will be also called Patent Document 1 and which corresponds to US 2009/0085102 A1) discloses a semiconductor device comprising a plurality of semiconductor pillars (silicon pillars) each having a size which allows full depletion, gate insulating films formed on respective outer circumferential surfaces of the plurality of semiconductor pillars, and gate electrodes covering respective side faces of the plurality of semiconductor pillars so as to fill gaps between the plurality of semiconductor pillars. That is, Patent Document 1 discloses the semiconductor device (the vertical transistor) having a characteristic equivalent to that of a structure in which a plurality of unit transistors are arranged in parallel. In the semiconductor device disclosed in Patent Document 1, a pillar lower diffusion layer electrically connects the silicon pillars to each other, and one of source/drain portions for the plurality of unit transistors is formed in common by the pillar lower diffusion layer which is formed between the silicon pillars and around the silicon pillars. In other words, in one vertical transistor disclosed in Patent Document 1, the pillar lower diffusion layer is shared and the plurality of silicon pillars is connected in parallel with each other.

On the other hand, in order to make the vertical transistor a high-breakdown voltage, a semiconductor transistor in which a plurality of vertical transistors is connected in series to each other is known. For instance, JP-A-2009-088134 (which will be also called Patent Document 2 and which corresponds to U.S. Pat. No. 8,154,076 B2) discloses a semiconductor device in which pillar upper diffusion layers and pillar lower diffusion layers of a plurality of unit transistors including semiconductor pillar having the same height are connected in series to each other and gate electrodes of the plurality of unit transistors are electrically connected to each other. In addition, Patent Document 2 also discloses, as a second exemplary embodiment, a semiconductor device in which a plurality of (two) unit transistors having a shared pillar lower diffusion layer is connected in series to each other.

As disclosed in Patent Document 2, in order to make the vertical transistors the high-breakdown voltage, the plurality of vertical transistors is connected in series.

In addition, as described in Patent Document 1, a semiconductor pillar group (the silicon pillar group) is formed by thinly dividing the semiconductor pillar (the silicon pillar) comprising the vertical transistor into a plurality of those and by arranging the plurality of semiconductor pillars in parallel in order to make a high current driving ability with a characteristic of the transistor maintained.

Accordingly, in order to have the high-breakdown voltage and the high current driving ability, it is advantageous in that a plurality of vertical transistors, each of which comprises a plurality of unit transistors which are connected in parallel with each other, are connected in series.

However, in the vertical transistor described in Patent Document 1, the plurality of silicon pillars is merely connected in parallel with each other in a state where pillar lower diffusion layers corresponding to the plurality of unit transistors connected in parallel are shared. In other words, in the vertical transistor disclosed in Patent Document 1, one pillar lower diffusion layer is formed individually.

For this reason, in a case where a plurality of vertical transistors each disclosed in Patent Document 1 is prepared individually and a high-breakdown voltage transistor is configured by connecting the plurality of vertical transistors in series, as disclosed in Patent Document 2, it is disadvantageous in that unevenness in characteristic of the individual vertical transistors easily occurs and a footprint thereof increases.

### SUMMARY

The present invention seeks to solve one or more of the above problems, or to improve upon those problems at least in part.

In one embodiment, there is provided a semiconductor device that includes a high-breakdown voltage transistor including at least first and second vertical transistors which are connected in series. The first vertical transistor comprises a first unit transistor group comprising a plurality of unit transistors each of which includes a semiconductor pillar. The second vertical transistor comprises a second unit transistor group comprising a plurality of unit transistors each of which includes a semiconductor pillar. The plurality of unit transistors constituting the first and the second unit transistor groups have pillar lower diffusion layers which are shared.

In another embodiment, there is provided a method of manufacturing a semiconductor device including a high-breakdown voltage transistor including at least first and second vertical transistors which are connected in series. The method comprising: forming an element isolation area on a substrate to form a first region, which is surrounded by the element isolation area, at which first and second vertical transistors should be manufactured; forming, in the first region, first and second semiconductor pillar groups each of which comprises a plurality of semiconductor pillars formed in a predetermined direction with a space therebetween; forming a pillar lower insulating film on a top face of the substrate exposed around each of the plurality of semiconductor pillars constituting the first and the second semiconductor pillar groups; implanting impurities in the substrate via the pillar lower insulating film to form, under the pillar lower insulating film, a pillar lower diffusion layer shared so as to electrically connect the plurality of semiconductor pillars constituting the first and the second semiconductor pillar groups; forming first and second gate insulating films on side faces of the plurality of semiconductor pillars constituting the first and the second semiconductor pillar groups, respectively; and forming first and second gate electrodes over the side faces of the plurality of semiconductor pillars constituting the first and the second semiconductor pillar groups via the first and the second gate insulating films so as to fill gaps between the plurality of semiconductor pillars constituting the first and the second semiconductor pillar groups, respectively.

### BRIEF DESCRIPTION OF THE DRAWINGS

The above features and advantages of the present invention will be more apparent from the following description of certain preferred embodiments taken in conjunction with the accompanying drawings, in which:

FIG. 1A is a plan view of a semiconductor device according to a first example of this invention;

FIG. 1B is a cross-sectional view taken on line X1-X1′ of FIG. 1A;

FIG. 1C is a cross-sectional view taken on line Y1-Y1′ of FIG. 1A;

FIG. 1D is a cross-sectional view taken on line Y2-Y2′ of FIG. 1A;

FIG. 2A is a plan view of a semiconductor device according a modified example of the first example in a case where a first unit transistor group and a second unit transistor are apart from each other to separate first gate electrodes and second gate electrodes;

FIG. 2B is a cross-sectional view taken on line X1-X1′ of FIG. 2A;

FIG. 3 is an equivalent circuit diagram of the semiconductor device illustrated in FIGS. 1A-1D;

FIG. 4 is an equivalent circuit diagram of the semiconductor device illustrated in FIGS. 2A-2B;

FIG. 5A is a plan view showing a process for forming a shallow trench isolation (STI) in a silicon substrate;

FIG. 5B is a cross-sectional view take on line X1-X1′ of FIG. 5A;

FIG. 6B is a cross-sectional view taken on line X1-X1′, showing a process for forming an insulating film and a mask film on an entire surface of the silicon substrate to pattern the insulating film and the mask film;

FIG. 7A is a plan view showing a process for forming ten silicon pillars and two gate-lifting pillars by dry-etching the silicon substrate exposed as the mask film as a mask;

FIG. 7B is a cross-sectional view taken on line X1-X1′ of FIG. 7A;

FIG. 7C is a cross-sectional view taken on line Y1-Y1′ of FIG. 7A;

FIG. 8B is a cross-sectional view taken on line X1-X1′, showing a process for forming sidewall films on side faces of the ten silicon pillars, of the two gate-lifting pillars, and of the mask films and for forming pillar lower insulating films on exposed parts of the silicon substrate;

FIG. 9B is a cross-sectional view taken on line X1-X1′, showing a process of forming pillar lower diffusion layers (drain diffusion layers) under the pillar lower insulating films by ion implantation and for removing the sidewall films and thermal oxide films;

FIG. 10A is a plan view showing a process for forming gate insulating films to side faces of the ten silicon pillars and of the two gate-lifting pillars and for forming gate electrodes on the side faces the ten silicon pillars and of the two gate-lifting pillars alone;

FIG. 10B is a cross-sectional view taken on line X1-X1′ of FIG. 10A;

FIG. 10C is a cross-sectional view taken on line Y1-Y1′ of FIG. 10A;

FIG. 11B is a cross-sectional view taken on line X1-X1′, showing a process for forming a first interlayer insulating film so as to imbed the ten silicon pillars and the two gate-lifting pillars and for forming a mask film;

FIG. 12B is a cross-sectional view taken on line X1-X1′, showing a process for forming a first opening portion by removing a part of the mask film and for forming second opening portions over the silicon pillars by removing the insulating film;

FIG. 13B is a cross-sectional view taken on line X1-X1′, showing a process for forming insulating films on inner walls of the second opening portions, for forming pillar upper diffusion layers (source diffusion layers) by implanting impurities from the second opening portions, for forming sidewall films to the inner walls of the second opening portions, and for exposing upper surfaces of the silicon pillars by removing the insulating films formed on the upper surfaces of the silicon pillars;

FIG. 14B is a cross-sectional view taken on line X1-X1′, showing a process for growing silicon plugs on the upper surfaces of the silicon pillars so as to stop up the second opening portions to make electrically contact with the pillar upper diffusion layers (the source diffusion layers);

FIG. 15B is a cross-sectional view taken on line X1-X1′, showing a process for depositing a second interlayer insulating layer, for depositing a stopper film, and for depositing a third interlayer insulating layer;

FIG. 16A is a plan view showing a process for forming contact holes;

FIG. 16B is a cross-sectional view taken on line X1-X1′ of FIG. 16A;

FIG. 17A is a plan view showing a process for forming metal contact plugs by embedding metal films in the insides of the contact holes;

FIG. 17B is a cross-sectional view taken on line X1-X1′ of FIG. 17A;

FIG. 18A is a plan view of a semiconductor device according to a second example of this invention;

FIG. 18B is a cross-sectional view taken on line X1-X1′ of FIG. 18A;

FIG. 18C is a cross-sectional view taken on line Y1-Y1′ of FIG. 18A;

FIG. 19A is a plan view of a semiconductor device according to a third example of this invention; and

FIG. 19B is a cross-sectional view taken on line X1-X1′ of FIG. 19A.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

The description will proceed to the gist of this invention.

In order to make vertical transistors a high-breakdown voltage, the plurality of vertical transistors is connected in series, as disclosed in the above-mentioned Patent Document 2. In addition, in order to make a high current driving ability with a characteristic of the transistor maintained, a semiconductor pillar group (the silicon pillar group) is formed by thinly dividing the semiconductor pillar (the silicon pillar) comprising the vertical transistor into a plurality of those and by arranging the plurality of semiconductor pillars in parallel, as disclosed in the above-mentioned Patent Document 1.

Accordingly, in order to have the high-breakdown voltage and the high current driving ability, it is advantageous in that a plurality of vertical transistors, each of which comprises a plurality of unit transistors which are connected in parallel with each other, are connected in series.

However, in prior art, as disclosed in Patent Document 1, the vertical transistor, which comprises pillar lower diffusion layers corresponding to the individual unit transistors connected in parallel, is formed individually. For this reason, in a case where a plurality of vertical transistors each disclosed in Patent Document 1 is prepared individually and a high-breakdown voltage transistor is configured by connecting the plurality of vertical transistors in series, as disclosed in Patent Document 2, it is disadvantageous in that unevenness in characteristic of the individual vertical transistors easily occurs and a footprint thereof increases.

Hence, in order to reduce the unevenness in characteristic of the individual vertical transistors and to decrease the footprint thereof, a semiconductor device according to an exemplary embodiment of this invention is configured so that pillar lower diffusion layers of the semiconductor pillars in each vertical transistor in which a plurality of unit transistors are connected in parallel with each other are shared and a plurality of vertical transistors is connected in series.

### Example 1

Referring now to Figures, a first example of this invention will be described.

The drawings for use in description herein are for the sake of describing the respective configurations and there may be cases where sizes, number, and so on in respective configurations are different from those of actual configurations. In addition, an XYZ coordinate system is set and arrangements of respective components will be described. In this coordinate system, the Z direction is a direction orthogonal to a surface of a silicon substrate, the X direction is a direction orthogonal to the Z direction in a horizontal surface concerning to the surface of the silicon substrate, and the Y direction is a direction orthogonal to the X direction in the horizontal surface concerning to the surface of the silicon substrate. In addition, the X direction is also called a first direction while the Y direction is also called a second direction. In the example being illustrated, the Y direction is a predetermined direction while the X direction is a direction orthogonal to the predetermined direction.

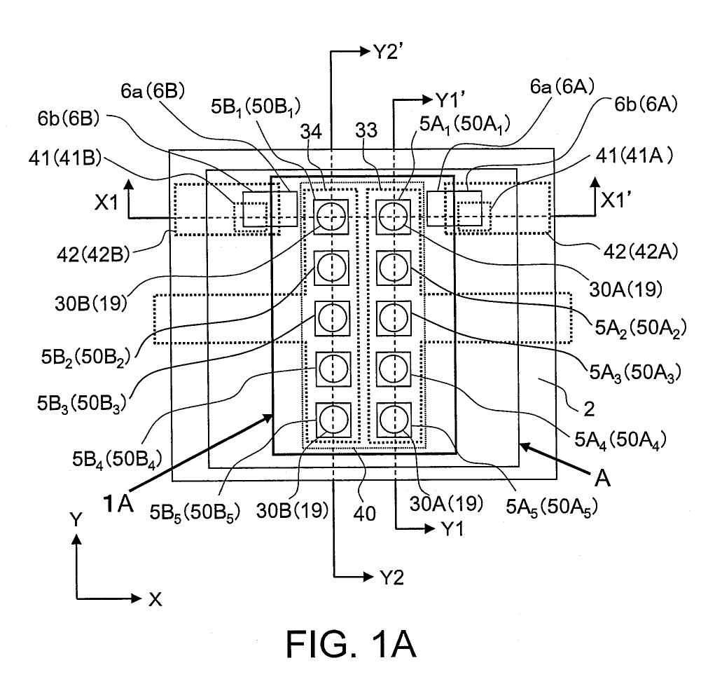

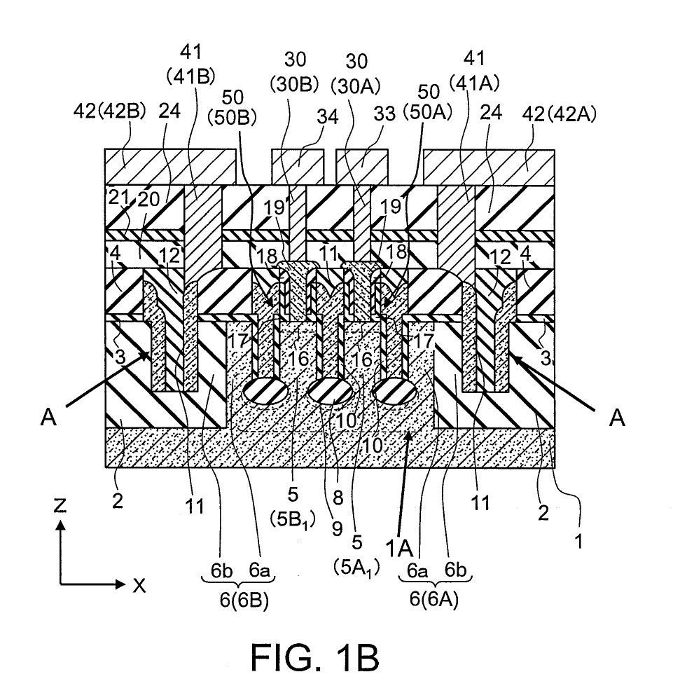

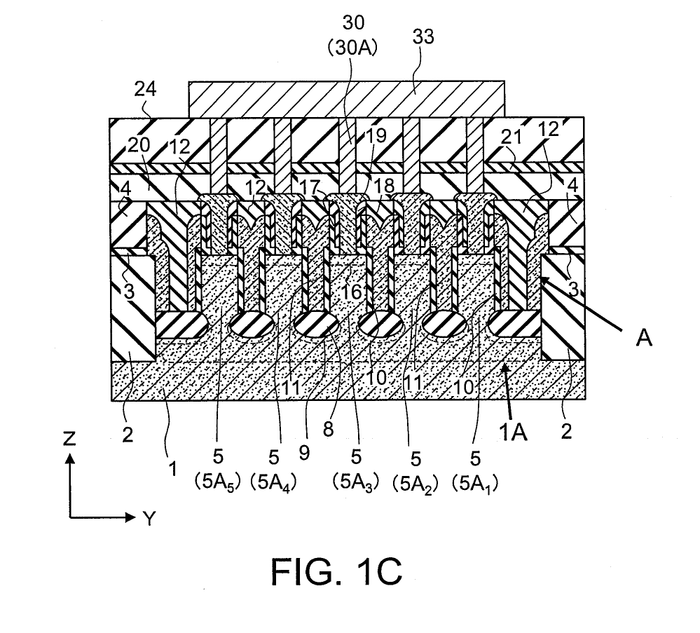

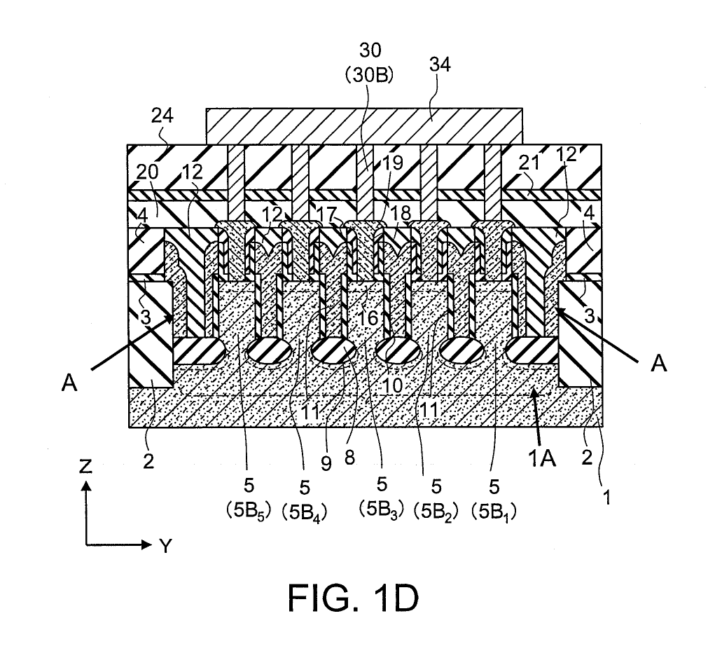

FIGS. 1A, 1B, 1C, and 1D are schematic views showing a configuration of a semiconductor device according to the first example of this invention. FIG. 1A is a plan view of the semiconductor device the first example. FIG. 1B is a cross-sectional view taken on line X1-X1′ of FIG. 1A. Likewise, FIG. 1C is a cross-sectional view taken on line Y1-Y1′ of FIG. 1A and FIG. 1D is a cross-sectional view taken on line Y2-Y2′ of FIG. 1A. However, in FIG. 1A, in order to define a layout condition of components, interlayer insulating films and wires positioned on contact plugs are put into a transmittance state and only in outline thereof is described.

Referring now to FIGS. 1B to 1D, a shallow trench isolation (STI) 2 serving as an element isolation region is provided in the silicon substrate at depicted at 1. A region surrounded by the STI 2 acts as an active region 1 A. The active region 1A is also called a first region.

As shown in FIG. 1A, in the active region 1A, ten silicon pillars (semiconductor pillars) 5A₁ to 5A₅ and 5B₁ to 5B₅ are provided in a standing manner. Specifically, in the active region 1A, a first silicon pillar group (a first semiconductor pillar group) 5A and a second silicon pillar group (a second semiconductor pillar group) 5B are provided in the standing manner. The first silicon pillar group (the first semiconductor pillar group) 5A comprises the five silicon pillars 5A₁ to 5A₅ disposed in the Y direction evenly spaced. The second silicon pillar group (the second semiconductor pillar group) 5B comprises the five silicon pillars 5B₁ to 5B₅ disposed in the Y direction evenly spaced so as to be arranged in parallel with the first silicon pillar group 5A. In this example, it is necessary that the number of the silicon pillars constituting the first silicon pillar group 5A is equal to the number of the silicon pillars constituting the second silicon pillar group 5B.

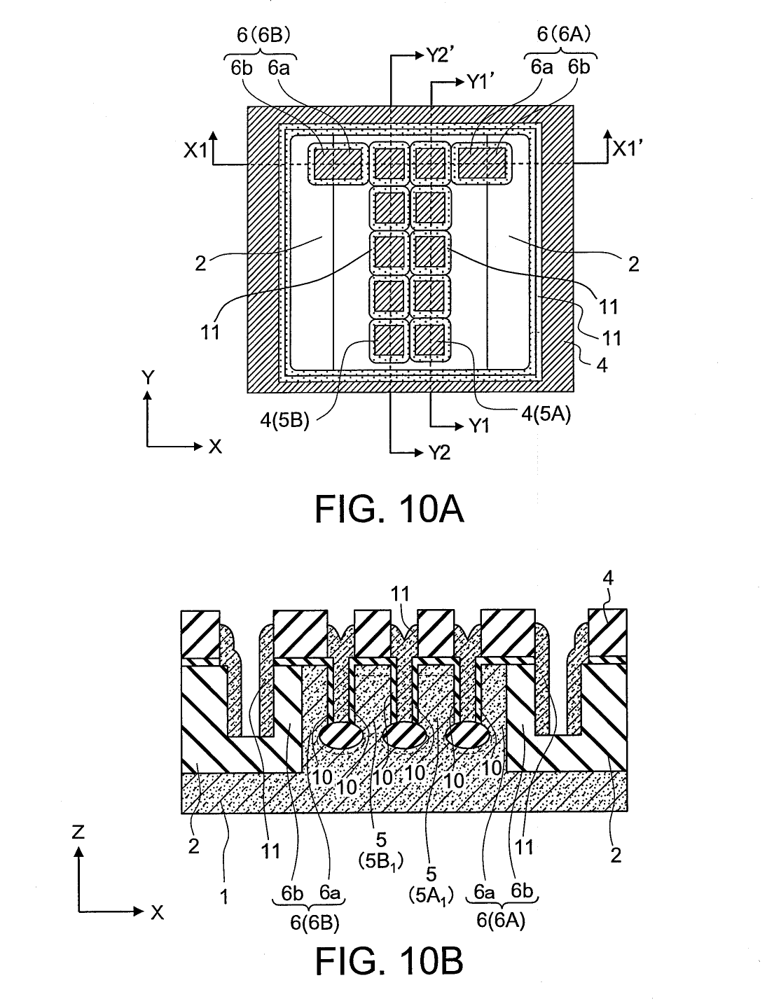

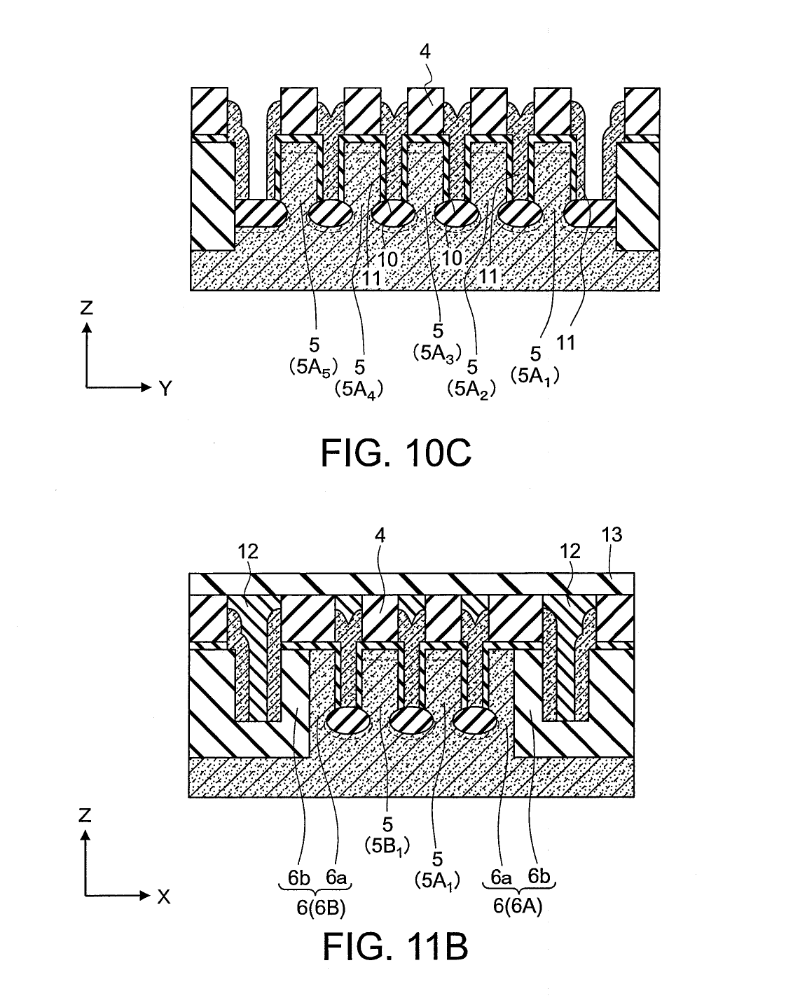

Herein, in the Y direction of FIG. 10, the five silicon pillars constituting the first silicon pillar group 5A are distinctly depicted as first through fifth silicon pillars 5A₁, 5A₂, 5A₃, 5A₄, and 5A₅ in the order towards from the right hand to left hand, respectively. Similarly, in the Y direction of FIG. 1D, the five silicon pillars constituting the second silicon pillar group 5B are distinctly depicted as sixth through tenth silicon pillars 5B₁, 5B₂, 5B₃, 5B₄, and 5B₅ in the order towards from the right hand to left hand, respectively.

Each silicon pillar comprises a silicon semiconductor layer having a pillar shape that forms a channel portion of a unit transistor 50. Accordingly, in the active region 1A, a first unit transistor group 50A comprising five unit transistors 50A₁ to 50A₅ and a second unit transistor group 50B comprising five unit transistors 50B₁ to 50B₅ are disposed.

Herein, the five unit transistors constituting the first unit transistor group 50A are distinctly depicted as first through fifth unit transistors 50A₁, 50A₂, 50A₃, 50A₄, and 50A₅ which correspond to the first through the fifth silicon pillars 5A₁ to 5A₅, respectively. Likewise, the five unit transistors constituting the second unit transistor group 50B are distinctly depicted as sixth through tenth unit transistors 50B₁, 50B₂, 50B₃, 50B₄, and 50B₅ which correspond to the sixth through the tenth silicon pillars 5B₁ to 5B₅, respectively.

Accordingly, in the first example, the first unit transistor group 50A disposed in the active region 1A constitutes a first vertical transistor while the second unit transistor group 50B disposed in the active region 1A constitutes a second vertical transistor. In the manner which will later be described, the first vertical transistor and the second vertical transistor are connected in series to constitute a high-breakdown voltage transistor. More specifically, the semiconductor device illustrated in FIGS. 1A-1D comprises a semiconductor device including a large current-ready high-breakdown voltage transistor which is disposed in the active region and which comprises the first vertical transistor in which the plurality of unit transistors are arranged in parallel and the second vertical transistor in which the plurality of unit transistors equal in number to that of the first vertical transistor are arranged in parallel, and in which the first vertical transistor and the second vertical transistor are connected in series to each other. Although each of the first silicon pillar group 5A and the second silicon pillar group 5B extending in the Y direction comprises the five silicon pillars by way of example, the number of the silicon pillars is not limited thereto and may be at least two.

The ten silicon pillars are arranged in the active region 1A partitioned by the STI 2 so as to have the same height entirely. Each silicon pillar has a thickness (i.e., the size of the cross-section thereof in a plane parallel to the silicon substrate 1) which allows full depletion.

Impurity diffused layers are provided on an upper end portion and a lower end portion of each silicon pillar. A pillar upper diffusion layer 16 positioned on the upper end portion of each silicon pillar comprises a source diffusion layer while a pillar lower diffusion layer 9 positioned on the lower end portion of each silicon pillar comprises a drain diffusion layer. A central portion of the silicon pillar that is sandwiched between the pillar upper diffusion layer 16 and the pillar lower diffusion layer 9 acts as a channel portion.

As shown in FIGS. 1A and 1B, first and second gate-lifting pillars (which will later be called dumpy pillars) 6A and 6B are disposed about (one end portions of) the first and the second silicon pillar groups 5A and 5B, respectively.

The dummy pillars 6 are used to supply a gate voltage to gate electrodes 11 constituting first and second vertical transistors in the manner which will later be described. Herein, the first dummy pillar 6A comprises a dummy silicon pillar 6a and a dummy insulating layer pillar 6b. The second dummy pillar 6B has a configuration which is similar to that of the first dummy pillar 6A. One side surface of the dummy silicon pillar 6a and one side surface of the dummy insulating layer pillar 6b make contact with each other to be integrated.

The silicon pillar groups 5 and the dummy pillars 6 are disposed within a pillar trench forming area A formed by etching a surface of the silicon substrate 1 and the STI 2. The dummy silicon pillar 6a comprises a semiconductor layer having a pillar shape that protrudes from the etched surface of the silicon substrate 1. The dummy insulating layer pillar 6b is formed by etching a surface of the STI 2 and comprises an insulating layer having a pillar shape that protrudes from the etched surface of the STI 2. As shown in FIG. 1B, each dummy pillar 6 functions as a protruding layer which increases the height of the gate electrode 11 and which shortens the distance between the gate electrode 11 and a gate-lifting wire 42A provided above the gate electrode 11. In each of the first and the second silicon pillar groups 5A and 5B, the interval between adjacent silicon pillars is double or less the thickness of each gate electrode 11. In addition, each of intervals between the dummy pillars 6A and 6B and the one end portions of the silicon pillar groups 5A and 5B that are disposed at the closest positions is also double or less the thickness of each gate electrode 11. Hereby, the individual silicon pillars constituting one silicon pillar group and the corresponding dummy pillar are connected by the gate electrodes 11.

As shown in FIGS. 1B to 1D, in the active region 1A, a pillar lower insulating film 8 bounded by a side face of the STI 2 is provided on the etched surface of the silicon substrate 1 which is exposed bottom surfaces around the respective silicon pillars and the dummy silicon pillars 6a. The pillar lower diffusion layer 9 is provided under the pillar lower insulating film 8 so as to overlap the pillar lower insulating film 8. The pillar lower diffusion layer 9 is electrically insulated from the gate electrodes 11 by means of the pillar lower insulating film 8. In addition, the pillar lower diffusion layer is configured to be shared to the first unit transistor group 50A and the second unit transistor group 50B in the active region 1A. The STI 2 has a bottom face which is formed deeper than a bottom face of the pillar lower diffusion layer 9 so that the pillar lower diffusion layers 9 respectively provided in areas which are adjacent across the STI 2 do not conduct each other. Throughout this specification, the pillar lower diffusion layer 9 will be called a first diffusion layer.

Accordingly, the first vertical transistor comprises the first unit transistor group (50A) having the first diffusion layer (9) shared. Likewise, the second vertical transistor comprises the second unit transistor group (50B) having the first diffusion layer (9) shared.

Gate insulating films 10 are formed on respective side faces of the respective silicon pillars 5 and of the dummy silicon pillars 6a. The gate electrodes 11 are formed over the respective side faces of the respective silicon pillars and of the dummy silicon pillars 6a with the gate insulating films 10 interposed therebetween. The gate electrodes 11 alone are also formed on side faces of the dummy insulating layer pillars 6b. Insulating films 3 are provided on upper surfaces of the dummy pillars 6 and mask films 4 are provided so as to cover upper surfaces of the insulating films 3.

As shown in FIG. 1B, the gate electrodes 11 are provided on side faces of the dummy pillars 6, side surfaces of the insulating films 3, and parts of side faces of the mask films 4. Gate insulating films 10 cover outer periphery surfaces of the respective silicon pillars and are connected to the pillar lower insulating films 8. The channel portions of the respective silicon pillars, the pillar upper diffusion layers 16, and the pillar lower diffusion layer 9 disposed the lower portions of the pillar lower insulating films 8 are electrically insulated from the gate electrodes 11 by means of the gate insulating films 10 and the pillar lower insulating films 8.

The gate electrodes 11 fill gaps between adjacent silicon pillars and gaps between the one end portions of the silicon pillar groups 5 and the dummy pillars 6. The gate electrodes 11 are formed so as to cover the gate insulating films 10 provided on the side faces of the respective silicon pillars and of the dummy pillars 6. As a result of this, a common gate electrode 11 is disposed to the plurality of unit transistors 50. In addition, the silicon pillar groups 5 and the dummy pillars 6 are provided with the common gate electrode 11.

Herein, the gate insulating films 10 constituting the first and the second semiconductor pillar groups 5A and 5B are called first and second gate insulating films, respectively. In addition, the gate electrodes corresponding to the first and the second gate insulating films are called first and second gate electrodes, respectively.

Accordingly, the first unit transistor group 50A comprises the first semiconductor pillar group 5A, the first gate insulating films 10, and the first gate electrodes 11. Similarly, the second unit transistor group 50B comprises the second semiconductor pillar group 5B, the second gate insulating films 10, and the second gate electrodes 11.

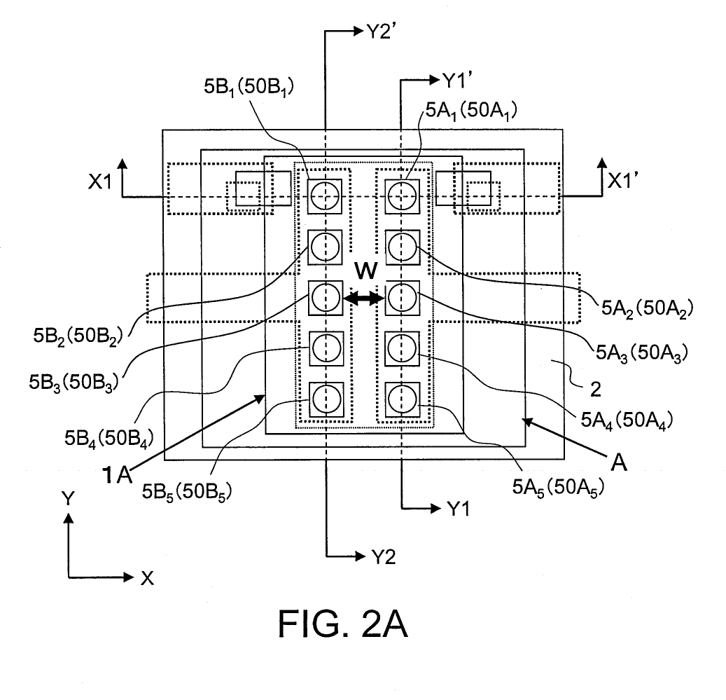

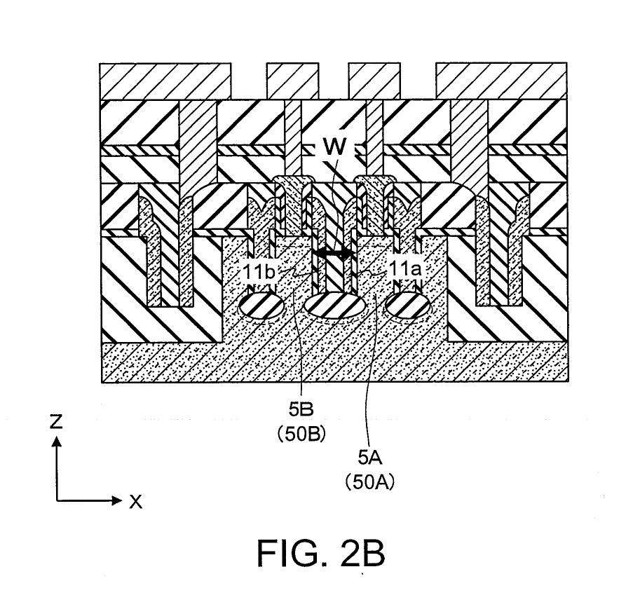

Although the first gate electrodes 11 and the second gate electrodes 11 are connected between the first silicon pillar group 5A and the second silicon pillar group 5B by making the interval between the first unit transistor group 50A and the second unit transistor group 50B in the X direction double or less of the thickness of each gate electrode in FIG. 1B, this invention is not limited thereto. The first and the second gate electrodes 11 may be separated between the first unit transistor group 50A and the second unit transistor group 50B by leaving a distance between the first silicon pillar group 5A extending in the Y direction and the second silicon pillar group 5B extending in the Y direction by double or more of each gate electrode, as shown in FIGS. 2A (a plan view) and 2B (a cross-section view taken on line X1-X1′) which will later be described.

As shown in FIG. 1B, the insulating films 3 are disposed on top faces of the STI 2 and of the dummy pillars 6. The mask films 4 are formed over the top faces of the STI 2 and of the dummy pillars 6 so as to cover the insulating films 3. A first interlayer insulating film 12 is formed so as to cover the gate electrodes 11 and the pillar lower insulating film 8. The first interlayer insulating film 12 is formed so as to fill in the pillar trench forming area A surrounded by the side faces of the STI 2, of the insulating films 3 stacked thereon, and of mask films 4 stacked thereon. A second interlayer insulating film 20 is formed on top faces of the mask films 4 and of the first interlayer insulating film 12. A stopper film 21 is provided so as to cover the second interlayer insulating film 20, and a third interlayer insulating film 24 is provided so as to cover the stopper film 21.

Gate-lifting wires 42 are disposed on a top face of the third interlayer insulating film 24. The gate-lifting wires 42 are connected to the gate electrodes 11 through gate metal contact plugs 41. Specifically, first and second gate-lifting wires 42A and 42B are provided on the top face of the third interlayer insulating film 24. The gate metal contact plugs 41 penetrate the third interlayer insulating film 24, the stopper film 21, the second interlayer insulating film 20, and the first interlayer insulating film 12. First and second gate metal contact plugs 41A and 41B are connected to the first and the second gate-lifting wires 42A and 42B, respectively.

The gate metal contact plugs 41 are formed at positions where the gate metal contact plugs 41 partially overlaps the dummy insulating film pillars 6b in the X-Y plane. More specifically, the mask films are disposed on the insulating films 3 positioned to the top faces of the dummy insulating film pillars 6b and the side faces of the mask films 4 and the side faces of the dummy insulating film pillars 6b are formed at the same plane. The gate metal contact plugs 41 are formed at the positions where the gate metal contact plugs 41 partially overlaps the gate electrodes 11 positioned to the side faces of the mask films 4 in the X-Y plane and connected to upper end portions of the gate electrodes 11. In conjunction with the dummy insulating film pillars 6b, the mask films 4 provided over the dummy insulating film pillars 6b serve as protruding layers which increase the height of the gate electrodes 11 and which shorten the distance between the gate electrodes 11 and the gate-lifting wires 42 provided above the gate electrodes 11. The gate electrodes 11 are connected to the gate-lifting wires 42 via the gate metal contact plugs 41.

First and second metal wires 33 and 34 are disposed on the third interlayer insulating film 24. The first metal wire 33 is connected to the respective pillar upper diffusion layers 16 of the first silicon pillar group 5A via silicon plugs 19 and first source metal contact plugs 30A. The pillar lower diffusion layer 9 is shared to the respective silicon pillars 5A₁ to 5A₅. Accordingly, the five unit transistors 50A₁ to 50A₅ constituting the first unit transistor group 50A are connected in parallel with each other by the fist metal wire 33.

On the other hand, the second metal wire 34 is connected to the respective pillar upper diffusion layers 16 of the second silicon pillar group 5B via silicon plugs 19 and second source metal contact plugs 30B. The pillar lower diffusion layer 9 is shared to the respective silicon pillars 5B₁ to 5B₅. Accordingly, the five unit transistors 50B₁ to 50B₅ constituting the second unit transistor group 50B are connected in parallel with each other by the second metal wire 34.

The silicon plugs 19 are enclosed with the first interlayer insulating film 12 and the gate electrodes 11. The first and the second metal contact plugs 30A and 30B penetrate the third interlayer insulating film 24, the stopper film 21, and the second interlayer insulating film 20. Each silicon plug 19 is formed by injecting (diffusing) impurities such as arsenic into silicon. In conjunction with the pillar upper diffusion layer 16, the silicon plug 19 configures one of source/drain sections of the unit transistor group 50. Sidewall films 18 and insulating films 17 are disposed on the side faces of the silicon plugs 19. Hence, the silicon plugs 19 are electrically insulated from the gate electrodes 11 by means of the sidewall films 18 and the insulating films 17.

The first diffusion layer (9) is connected to the plurality of unit transistors (50A₁ to 50A₅) constituting the first unit transistor group (50A) and to the plurality of unit transistors (50B₁ to 50B₅) constituting the second unit transistor group (50B). That is, the first diffusion layer (9) connects the first unit transistor group (50A) with the second unit transistor group (50B) in series.

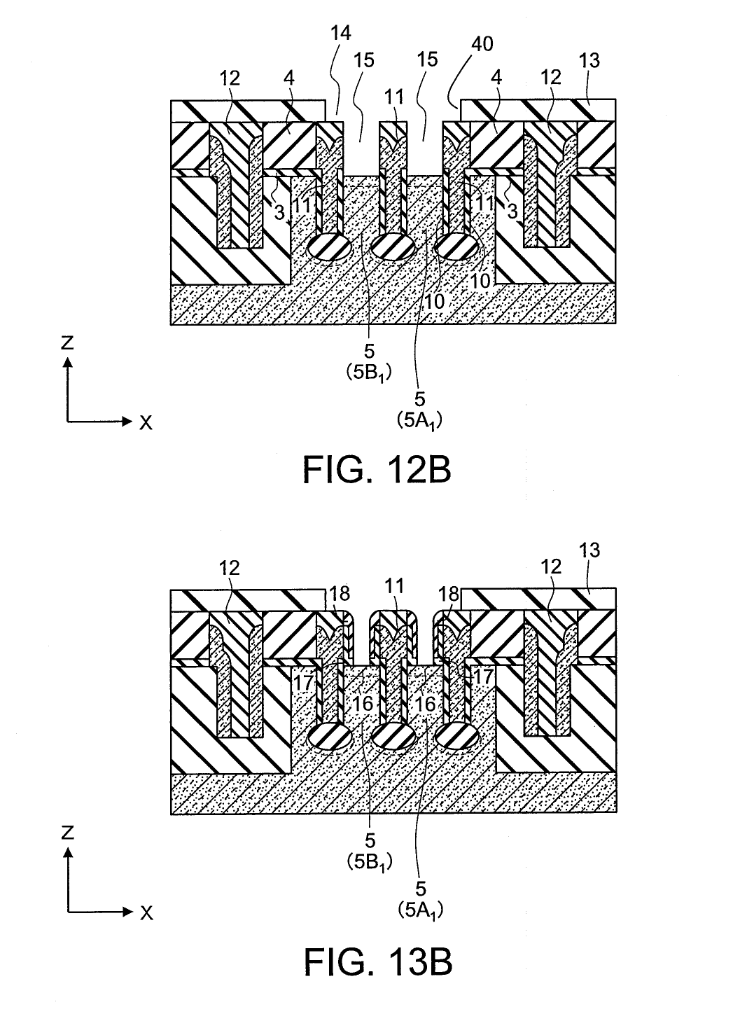

Although the description will later be described in conjunction with FIG. 12B, a pattern 40 depicted in FIG. 1A represents an area in a mask film 13 (not shown) that is removed for providing the silicon plugs 19 and the inside of the pattern 40 acts as a first opening portion 14 (not shown).

Although the first and the second dummy pillars 6A and 6B and the first and the second silicon pillar groups 5A and 5B each of in which the five silicon pillars are disposed in the Y direction are disposed in the X direction and the first and the second metal wires 33 and 34 and the gate-lifting wires 42 are disposed so as to overlap therewith in FIG. 1A, an arrangement of respective components is not limited thereto. A layout of the respective components may be arbitrary and various modifications may be. For example, a plane shape of each silicon pillar may be a circle or a polygon other than the rectangle. In addition, a plane arrangement of the silicon pillar group 5 may extend in the X direction and may be disposed in a matrix fashion in the X and Y directions. Furthermore, a size and a shape of each dummy pillar 6 are particularly not limited.

In addition, by leaving the interval W between the first and the second silicon pillar groups 5A and 5B by double or more of the thickness of each gate electrode 11 as shown in FIGS. 2A and 2B, it is possible to control the respective unit transistor groups, individually, so that a first gate electrode 11a for the first unit transistor group 50A and a second gate electrode 11b for the second unit transistor group 50B are separated from each other. Although other configurations in FIGS. 2A and 2B are identical with those in FIGS. 1A and 1B, detailed description thereof is omitted.

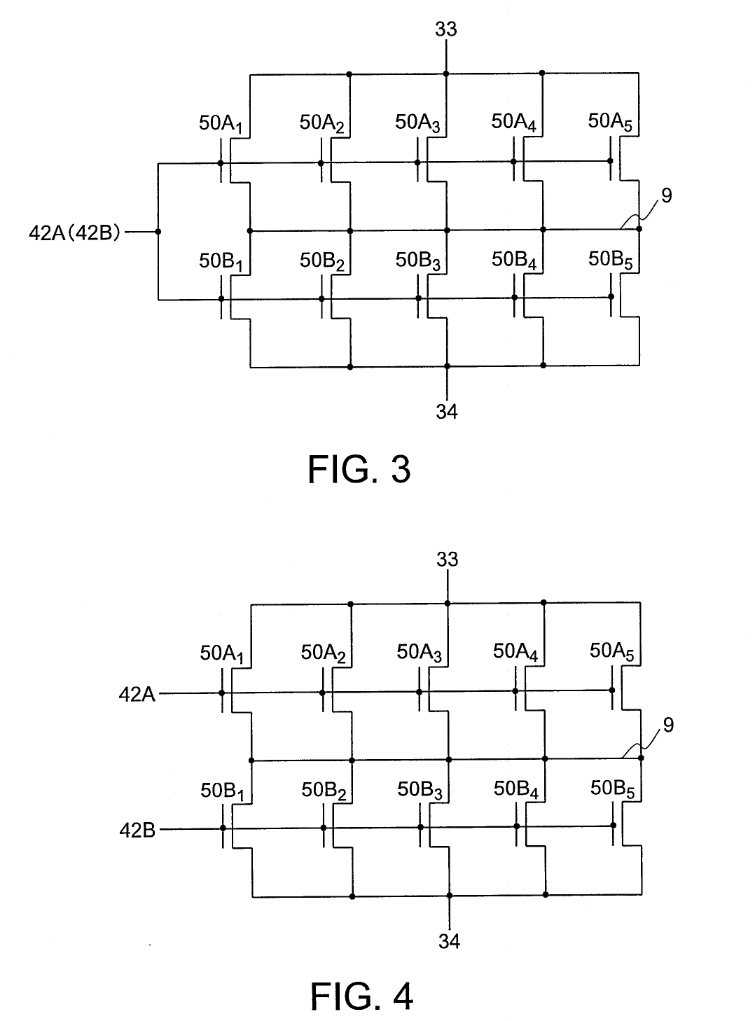

FIG. 3 shows an equivalent circuit of the semiconductor device illustrated in FIGS. 1A and 1B in a case where the interval W between the first and the second silicon pillar groups 5A and 5B is double or less of the thickness of each gate electrode 11 and the first gate electrode 11 for the first unit transistor group 50A and the second gate electrode 11 for the second unit transistor group 50B are disposed so as to come into contact with them. The pillar upper diffusion layers 16 of the five unit transistors 50A₁ to 50A₅ constituting the first unit transistor group 50A are mutually connected to each other by sharing the first metal wire 33 while the pillar upper diffusion layers 16 of the five unit transistors 50B₁ to 50B₅ constituting the second unit transistor group 50B are mutually connected to each other by sharing the second metal wire 34. In addition, all of the unit transistors are mutually connected to each other by sharing the pillar lower diffusion layer 9. Furthermore, the gate electrodes of all of the unit transistors are commonality by sharing the first and the second gate-lifting wires 42A and 42B.

FIG. 4 shows an equivalent circuit of the semiconductor device illustrated in FIGS. 2A and 2B in a case where the interval W between the first and the second silicon pillar groups 5A and 5B is double or more of the thickness of each gate electrode 11 and the first gate electrode 11a for the first unit transistor group 50A and the second gate electrode 11b for the second unit transistor group 50B are disposed so as to separate from each other. In this event, although a configuration where the pillar upper diffusion layers 16 are connected by sharing the first or the second metal wires 33 or 34 is identical with that in FIGS. 1A and 1B, the gate electrodes are configured so as to connected to the first and the second gate-lifting wires 42A and 42B, independently, and the semiconductor device is therefore configured so as to be capable of independently controlling the first gate electrode 11a for the first unit transistor group 50A and the second gate electrode 11b for the second unit transistor group 50B, respectively.

In the manner which is described above, the semiconductor device according to this example comprises the first vertical transistor comprising the first unit transistor group 50A in which the five unit transistors 50A₁ to 50A₅ are connected in parallel with each other by means of the first metal wire 33, and the second vertical transistor comprising the second unit transistor group 50B in which the five unit transistors 50B₁ to 50B₅ are connected in parallel with each other by means of the second metal wire 34. In addition, the semiconductor device according to this example is configured so that the first vertical transistor and the second vertical transistor are connected in series via the pillar lower diffusion layer 9. More specifically, the semiconductor device according to this example comprises the first metal wire 33, the first vertical transistor connected to the first metal wire 33, the second vertical transistor connected to the first vertical transistor via the shared pillar lower diffusion layer 9, and the second metal wire 34 connected to the second vertical transistor.

With the above-mentioned configuration, when a current flows from the pillar upper diffusion layers 16 toward the pillar lower diffusion layer 9 in the first vertical transistor, a current flows from the pillar lower diffusion layer 9 toward the pillar upper diffusion layers 16 in the second vertical transistor. Accordingly, the first vertical transistor and the second vertical transistor serve to cancel unevenness in characteristic unique to the vertical transistor arising from a direction in which a current flows, the serial transistor according to this example has always an averaged voltage-current characteristic, and it is therefore possible to provide a stable transistor operation.

Now, description will be made as regards a method of manufacturing the semiconductor device according to the first example in detail.

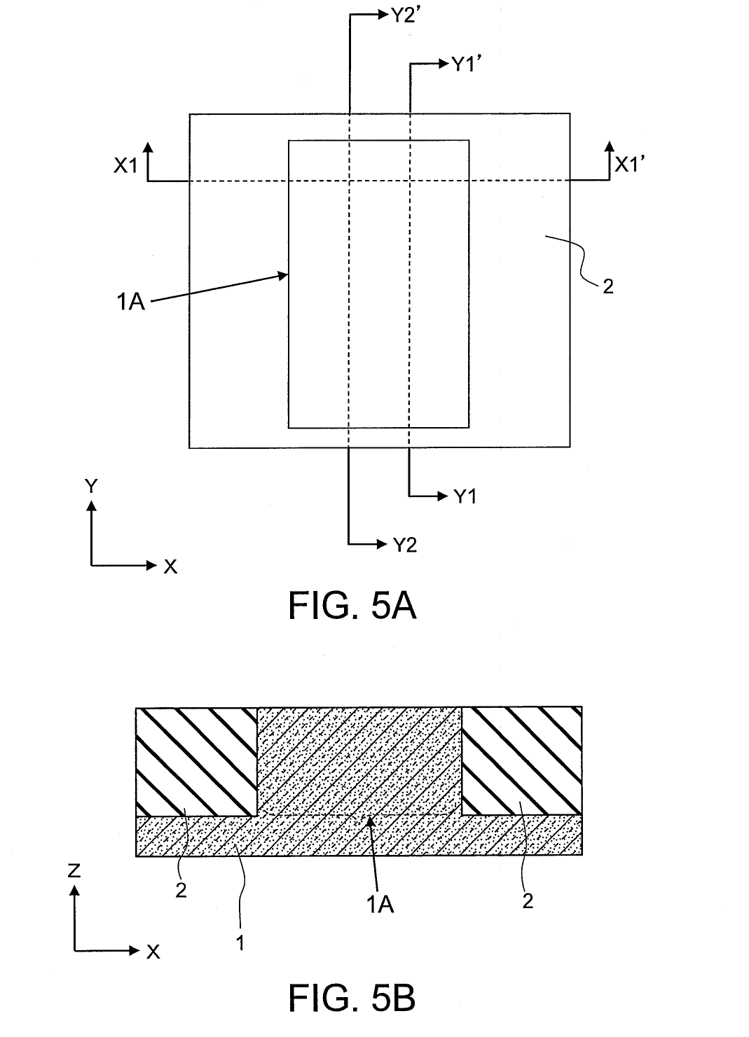

FIGS. 5-17 are process diagrams for use in describing the method of manufacturing the semiconductor device according to the first example. In each (FIG. O) of FIGS. 5-17, FIG. OA is a plan view of the semiconductor device in each manufacturing process, and FIG. OB is a cross-sectional view taken on line X1-X1′ of FIG. OA. Likewise, FIG. OC is a cross-sectional view taken on line Y1-Y1′ of FIG. OA, and FIG. OD is a cross-sectional view taken on line Y2-Y2′ of FIG. OA. In addition, the description of each manufacturing process will be mainly carried out using the cross-sectional view of FIG. OB, as appropriate, supplementary description of FIG. OB will be carried out by adding the drawings of FIG. OA, FIG. OC, and FIG. OD. Furthermore, in FIG. OA, components serving as foundations of the top layer are depicted at broken lines in order to make arrangement conditions of the respective components clear.

First, as shown in FIGS. 5A and 5B, in a surface of a silicon substrate 1 comprising a p-type monocrystalline silicon, an STI 2 is formed by a known shallow trench isolation (STI) method. The STI 2 serves as an element separation area having a depth of 250 nm. A region surrounded by the STI 2 becomes an active region 1A.

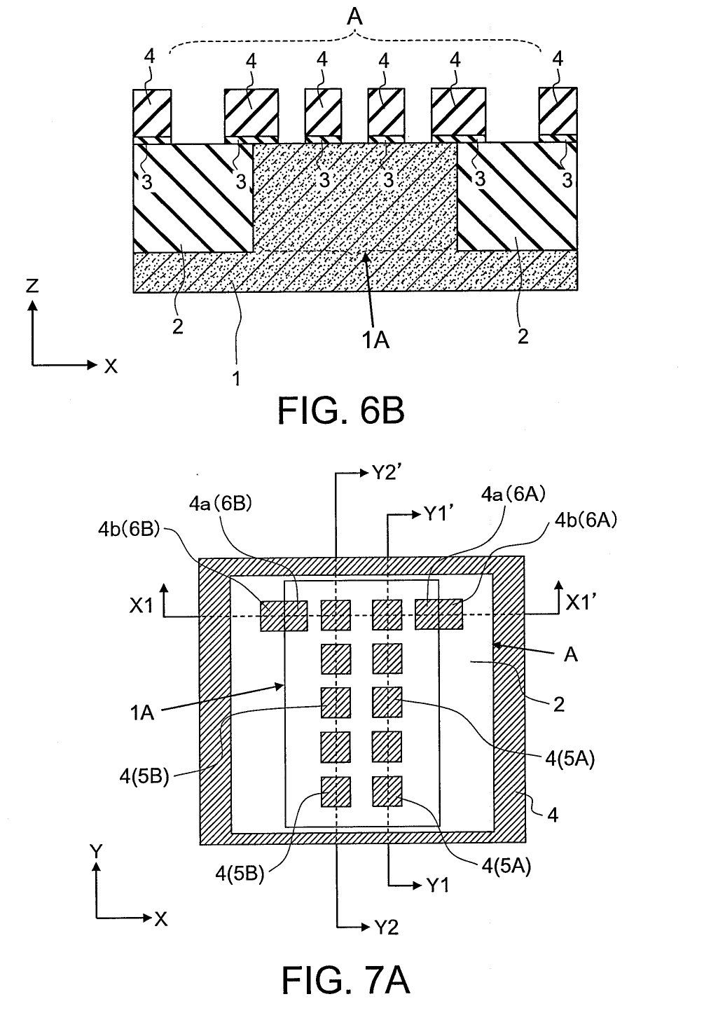

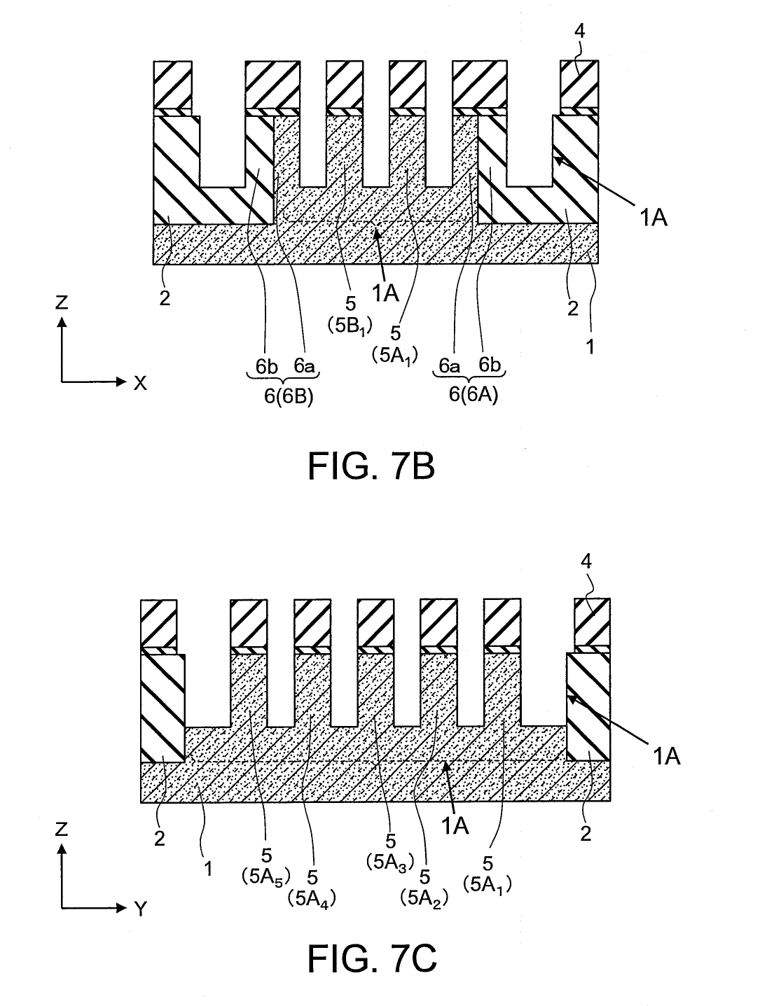

Next, as shown in FIG. 6B, an insulating film 3 comprising a silicon oxide film of 5 nm in thickness is formed on the silicon substrate 1 by a chemical vapor deposition (CVD) method, and then a mask film 4 comprising a silicon nitride film of 120 nm in thickness is formed on the insulating film 3. Next, the insulating film 3 and the mask film 4 are patterned using a photolithography process and a dry etching process. In this event, in patterned opening portions, a top face of the silicon substrate 1 and a top surface of the STI 2 are exposed, respectively. Thereby, as shown in FIGS. 6B and 7A, a pillar trench forming area A is partitioned, and mask film patterns 4 corresponding ten silicon pillars (5A, 5B) and mask film patterns 4 corresponding two dummy pillars (6A, 6B) are formed in the pillar trench forming area A. The mask film patterns 4 corresponding two dummy pillars (6A, 6B) are formed in positions which extend over the active region 1A and the STI 2.

Next, as shown in FIGS. 7A, 7B, and 7C, the silicon substrate 1 and the STI 2 having the exposed top faces are anisotropic dry-etched using the mask film patterns 4 as masks. A depth of etching is 150 nm. Hereby, the ten silicon pillars 5 serving as the channels for the unit transistors and the two dummy pillars 6 for connecting gate electrodes to upper layer portions are formed.

Specifically speaking, the ten silicon pillars 5A₁ to 5A₅ and 5B₁ to 5B₅ each constituting a unit transistor are arranged in the active region 1A in the Y direction (the predetermined direction), respectively, to form parallel two rows of silicon pillar groups 5 which comprises a first silicon pillar group 5A and a second silicon pillar group 5B. The silicon pillars constituting the first silicon pillar group 5A and the silicon pillars constituting the second silicon pillar group 5B are equal in number to each other. The interval (gap) between the respective silicon pillars is made double or less the film thickness of each gate electrode which will be formed later. Likewise, one dummy pillar 6 is arranged so as to be adjacent to one end portion of each silicon pillar group 5 with the interval of double or less the film thickness of each gate electrode. The dummy pillar 6 comprises a composite pillar into which a dummy silicon pillar 6a formed in the active region 1A and a dummy insulating layer pillar 6b formed in the STI 2 are incorporated so as to make contact with one side faces thereof. A thickness (i.e., an area of the cross-section in a plane parallel to the silicon substrate 1) of each silicon pillar constituting the channel portion of the transistor is a value which allows full depletion and is the same. The dummy pillar 6 can be any size. Thus, the size of the dummy pillar 6 may be different from that of the silicon pillar for forming the channel portion.

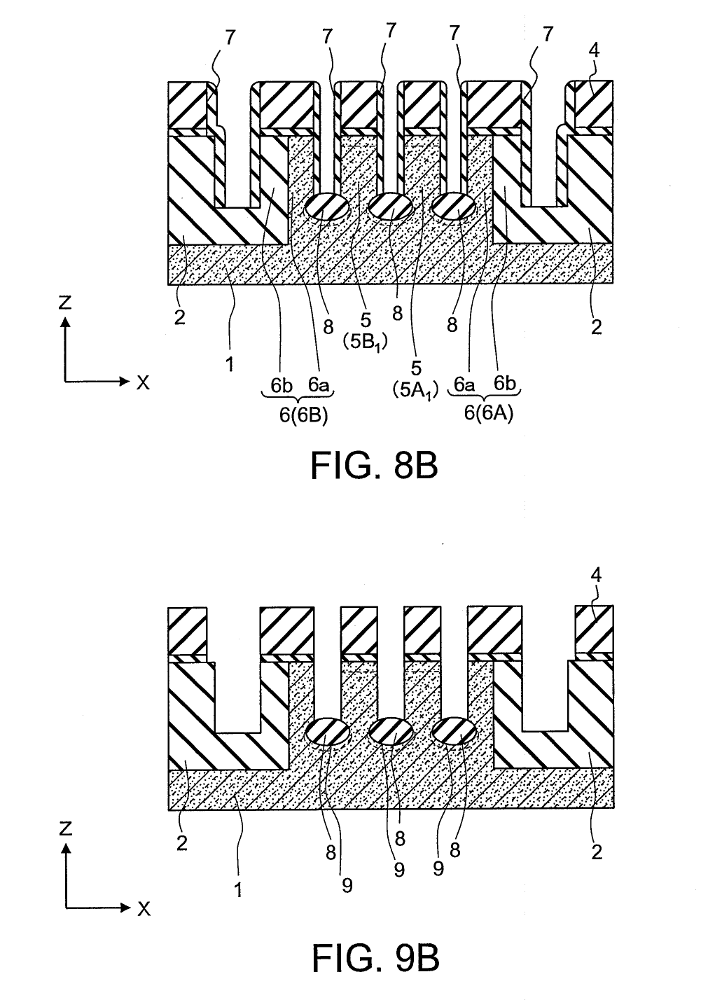

Subsequently, as shown in FIG. 8B, protection oxide films (not shown) of 1 nm in thickness are formed on the side faces of the respective silicon pillars and of the dummy silicon pillars 6a by the thermal oxidization method, and a silicon nitride film of 5 nm in thickness is deposited on the entire surface by the CVD method. Thereafter, the entire surface is etched back to form sidewall films 7 on the side faces of the respective silicon pillars, of the dummy pillars 6, and of the mask film patterns 4. Next, in the active region 1A, by the thermal oxidation of the silicon substrate 1 having the exposed top face positioned about bottom portions of the respective pillars, a pillar lower insulating firm 8 comprising a silicon oxide film of 20 nm in thickness is formed. At this time, the side faces and the top faces of the respective silicon pillars and the dummy pillars 6 are not formed with the silicon oxide films because they are covered with the silicon nitride film.

Subsequently, as shown in FIG. 9B, a lower diffused layer 9 is formed under the pillar lower insulating film 8. Specifically speaking, by ion implantation, an n-type impurity such as arsenic is introduced in the silicon substrate 1. Thereafter, a heat treatment at temperature of 1000° C. for 10 seconds is subjected to activate the impurity and to form the pillar lower diffusion layer 9 comprising an n-type impurity diffused layer. Subsequently, by the dry etching method or a wet etching method, the sidewall films 7 and the protection oxide films are removed.

Subsequently, as shown in FIGS. 10A, 10B, and 10C, by the thermal oxidation method, gate insulating films 10 comprising silicon oxide films each having a thickness of 4 nm are formed on the side faces of the respective silicon pillars and the dummy silicon pillars 6a. Next, a polycrystalline silicon film containing impurities of 20 nm in thickness for forming gate electrodes is deposited over the entire surface of the silicon substrate 1, and the entire surface is etched back to form the gate electrodes 11 over the side faces of the respective silicon pillars and the dummy pillars 6. In this event, the gate electrode 11 is also formed on the side face of the STI 2.

As shown in FIGS. 10B and 10C, inasmuch as the interval between adjacent silicon pillars and the intervals between the one end portions of the silicon pillar groups 5 and the dummy pillars 6 are double or less the film thickness of each gate electrode 11, the gaps between the adjacent silicon pillars and the gaps between the one end portions of the silicon pillar groups 5 and the dummy pillars 6 are completely buried by the gate electrodes 11. Although the first gate electrode 11 constituting the first silicon pillar group 5A and the second gate electrode 11 constituting the second silicon pillar group 5B are put into a state where they are connected between the first silicon pillar group 5A and the second silicon pillar group 5B in FIG. 10A, this invention is not limited thereto. As shown in FIGS. 2A and 2B, an interval W between the first silicon pillar group 5A extending in the Y direction and the second silicon pillar group 5B extending in the Y direction may keep a distance of double or more the film thickness of each gate electrode 11 so that the first and the second gate electrodes 11a and 11b are separated from each other between the first unit transistor group 50A and the second unit transistor group 50B.

Subsequently, as shown in FIG. 11B, a fist interlayer insulating film 12 comprising a silicon oxide film is formed by the CVD method so as to bury the respective silicon pillars and the dummy pillars 6. Next, by the CMP method, the first interlayer insulting film 12 is flattened so as to expose upper surfaces of the mask film patters 4 and then, by the CVD method, a mask film 13 serving as a silicon oxide film of 50 nm in thickness is deposited.

Subsequently, as shown in FIG. 12B, a part of the mask film 13 is removed using the photolithography method and the etching method to form a first opening portion 14. In the first opening portion 14, top faces of the mask film patterns 4 positioned over the respective silicon pillars are exposed. A pattern 40 of the removed mask film 13 forming the first opening portion 14 is formed only portions where the silicon pillars are disposed, as shown in FIG. 1A. That is, it is formed as the pattern 40 for surrounding the ten silicon pillars 5A₁ to 5A₅ and 5B₁ to 5B₅.

Subsequently, the exposed mask film patterns 4 are selectively removed by the wet etching and the insulating film 3 is removed to form second opening portions 15 over the respective silicon pillars. The second opening portions 15 have bottom surfaces in which the upper surfaces of the respective silicon pillars are exposed and have side faces in which parts of the gate electrodes 11 comprising the polysilicon film are exposed.

Next, as shown in FIG. 13B, by the thermal oxidation method, insulating films 17 comprising silicon oxide films are formed on the side walls of the gate electrodes 11 exposed in the second opening portions 15 and on the top faces of the respective silicon pillars 5. Subsequently, n-type impurities such as phosphorus or arsenic are ion-injected into the upper portions of the respective silicon pillars 5 through the second opening portions 15 and a heat treatment for activating the impurities to form pillar upper diffusion layers 16. In addition, a silicon nitride film of 5 nm in thickness is deposited in the entire surface by the CVD method, and thereafter an etch-back process is performed to form sidewall films 18 in inner walls of the second opening portions 15. In forming the sidewall films 18, the insulting films 17 formed on the top faces of the respective silicon pillars are removed to expose the top faces of the respective silicon pillars. In this event, the insulating films 17 remain under the sidewall films 18 and on exposed surfaces of the gate electrodes 11 in the second opening portions 15. The sidewall films 18 play a role in ensuring to insulate the gate electrodes 11 from silicon plugs which will be formed later.

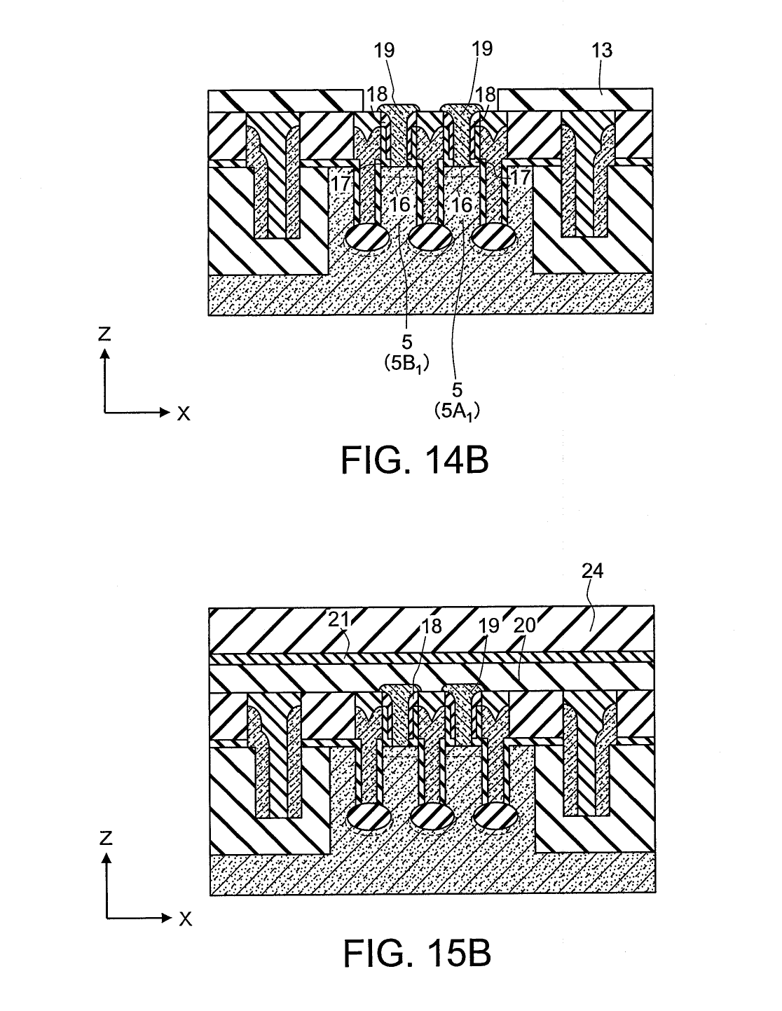

Subsequently, as shown in FIG. 14B, using a selective epitaxial growth method using, as seeds, the top faces of the respective silicon pillars 5 comprising the monocrystalline silicon, the monocystalline silicon are grown so as to stop up the second opening portions 15 to form silicon plugs 19. Thereafter, ions such as arsenic ions are injected to make the silicon plugs 19 n-type conductors, thereby the silicon plugs 19 electrically connecting the pillar upper diffusion layers 16 formed on the upper portions of the respective silicon pillars.

Subsequently, as shown in FIG. 15B, a second interlayer insulating film 20 comprising a silicon oxide film is formed so as to bury the first opening portion 14 by the CVD method. The mask film 13 comprising the silicon oxide film is integrated with the second interlayer insulating film 20. Thereafter, a stopper film 21 comprising a silicon nitride film of 20 nm in thickness is deposited by the CVD method. Then, a third interlayer insulting film 24 comprising a silicon oxide film of 150 nm in thickness is deposited by the CDV method.

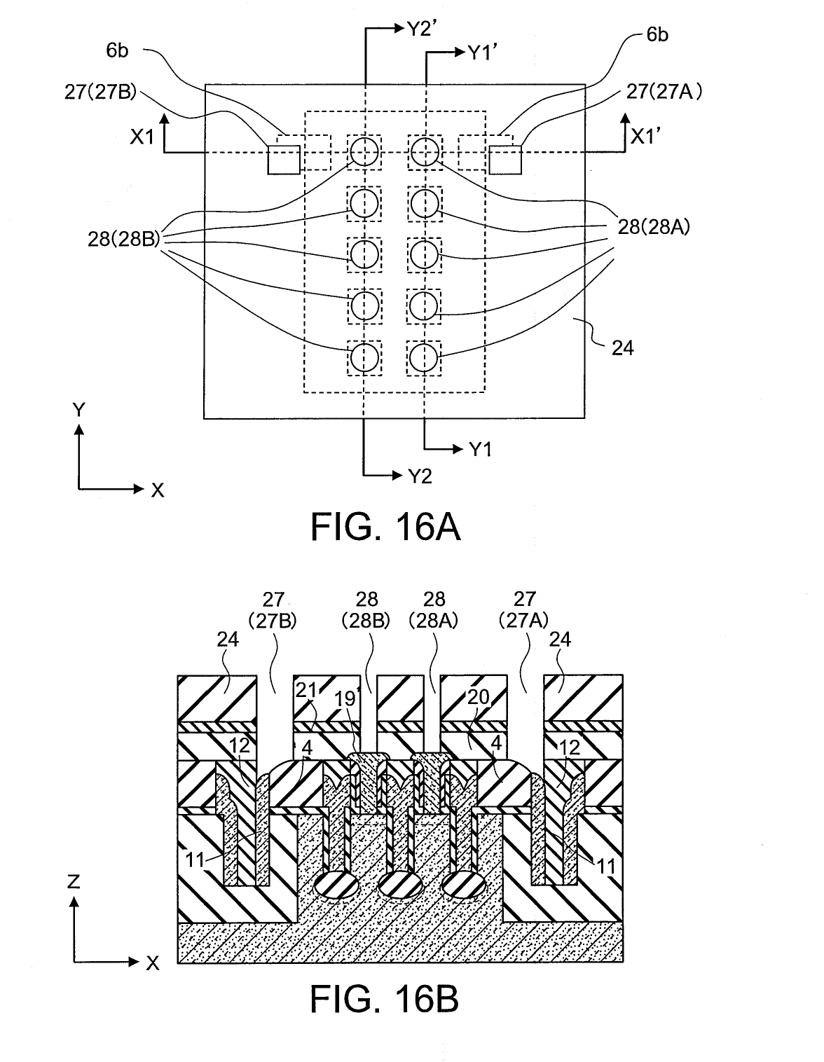

Next, as shown in FIGS. 16A and 16B, using the photolithography method and the dry etching method, first contact holes 27 (27A, 27B) are formed over the respective dummy insulating film pillars 6b constituting the first and the second dummy pillars 6A and 6B. In addition, second contact holes 28 (28A, 28B) are formed over the silicon pillars (5A₁ to 5A₅ and 5B₁ to 5B₅).

Although a depth up to the gate electrodes 11 is controlled by temporally stopping the dry etching at the stopper film 21 in formation of the first contact holes 27, the top faces of the dummy insulating film pillars 6b are not etched because they are protected with the remaining mask film patterns 4. Inasmuch as the first contact holes 27 are formed at the position displaced from a center of the dummy insulating film pillars 6b, at the bottom portion thereof, the mask film patterns 4 formed over the dummy insulating film pillars 6b and parts of the gate electrodes 11 formed on the side faces of the dummy insulating film pillars 6b are exposed.

Furthermore, the second contact holes 28 have bottom portions at which at least parts of the contact plugs 19 are exposed. The first and the second contact holes 27 and 28 may be formed at the same time or may be formed individually.

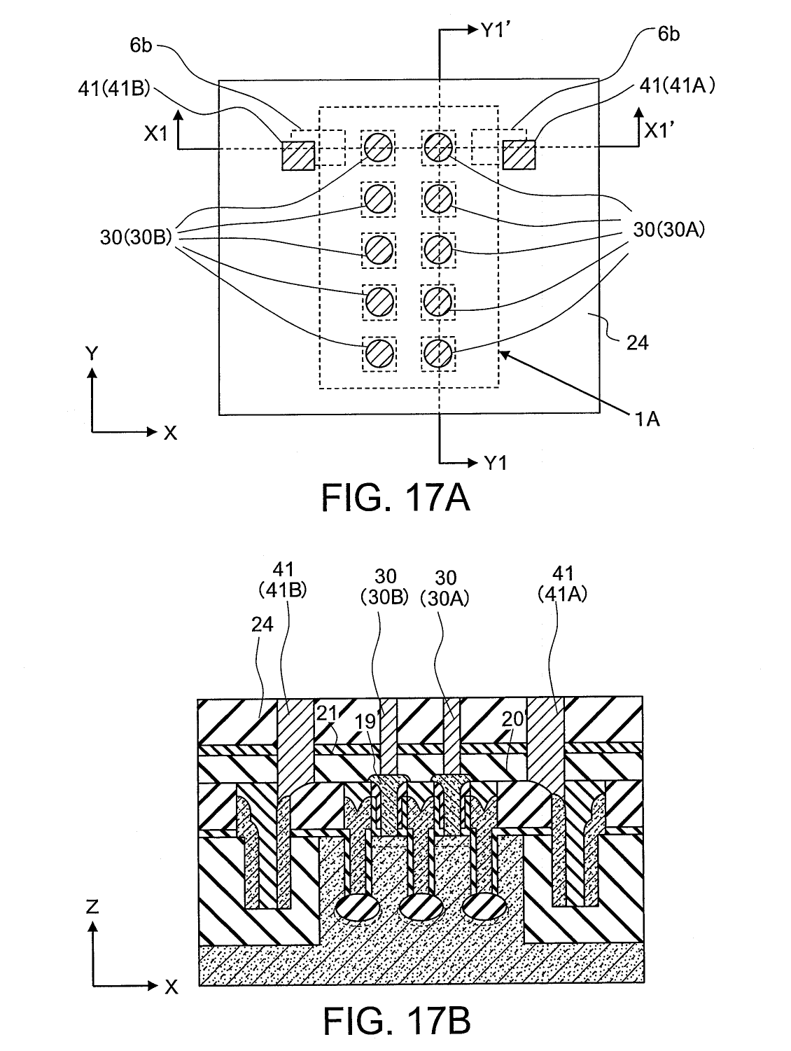

Next, as shown in FIGS. 17A and 17B, by the CVD method, the first and the second contact holes 27 and 28 are filled by depositing a metal film made from titanium (Ti), titanium nitride (TiN), and tungsten (W) in order so as to cover the third interlayer insulating film 24. Subsequently, by using the CMP method, the metal film on the third interlayer insulating film 24 is removed to form metal contact plugs 30 for the silicon plugs 19 and gate metal contact plugs 41 for the gate electrodes 11.

Next, as shown in FIGS. 1A to 1D, a first metal wire 33, a second metal wire 34, and gate-lifting wires 42, each of which is made from tungsten (W) and tungsten nitride (WN), are formed by a spatter method.

In this event, a first gate metal contact plug 41A of the pillar trench forming area A is connected to a first gate-lifting wire 42A. In addition, a second gate metal contact plug 41B of the pillar trench forming area A is connected to a second gate-lifting wire 42B.

Connected to the pillar upper diffusion layers 16 formed in the first silicon pillar group 5A via the silicon plugs 19, five first metal contact plugs 30A are connected to the first metal wire 33. Hence, the five silicon pillars 5A₁ to 5A₅ constituting the first silicon pillar group 5A are connected in parallel with each other.

Furthermore, connected to the pillar upper diffusion layers 16 formed in the second silicon pillar group 5B via the silicon plugs 19, five second metal contact plugs 30B are connected to the second metal wire 34. Hence, the five silicon pillars 5B₁ to 5B₅ constituting the second silicon pillar group 5B are connected in parallel with each other.

Accordingly, the first unit transistor group 50A comprising the first silicon pillar group 5A is configured so that the five silicon pillars 5A₁ to 5A₅ share the pillar lower diffusion layer 9 and are connected in parallel with each other by the first metal wire 33. In addition, the second unit transistor group 50B comprising the second silicon pillar group 5B is configured so that the five silicon pillars 5B₁ to 5B₅ share the pillar lower diffusion layer 9 and are connected in parallel with each other by the second metal wire 34. Furthermore, the semiconductor device according to the first example is laid out so that the first vertical transistor comprising the first unit transistor group 50A and the second vertical transistor comprising the second unit transistor group 50B are connected in series with each other.

In accordance with the semiconductor device of the first example described above, the following advantages are obtained.

(1) In the semiconductor device in which the first vertical transistor comprising the plurality of unit transistors 50A₁ to 50A₅ connected in parallel with each other via the first metal wire 33 and the second vertical transistor comprising the plurality of unit transistors 50B₁ to 50B₅ connected in parallel with each other via the second metal wire 34 are connected in series with each other, the pillar lower diffusion layers for the plurality of unit transistors 50A₁ to 50A₅ constituting the first vertical transistor are shared in the same active region while the pillar lower diffusion layers for the plurality of unit transistors 50B₁ to 50B₅ constituting the second vertical transistor are shared in the same active region. Accordingly, as compared with, for example, a case where the pillar lower diffusion layers for the plurality of unit transistors 50A₁ to 50A₅ constituting the first vertical transistor are separated to be formed individually, it is possible to render a current-voltage characteristic of the individual unit transistors 50A₁ to 50A₅ uniform, and it is therefore possible to provide the high-breakdown voltage transistor for supporting a large current having the stable characteristic.

(2) Inasmuch as the lower diffusion layers for the plurality of unit transistors constituting one unit transistor group are shared by connecting them to the same pillar lower diffusion layer 9 positioned in one active region, it is possible to obtain a stable drain current even if a part of the plurality of unit transistors is out of order.

This is for the following reason. It is assumed that the amount of a current flowing in one unit transistor is “1”. In a case where the five unit transistors constituting one unit transistor, namely, the five pillar lower diffusion layers are formed in different active regions, respectively, in FIG. 1A, if one of the five unit transistors is out of order, the amount of the current of “4” flows in the remaining four unit transistors. However, in FIG. 1A, all of the unit transistors constituting the first unit transistor group 50A are connected to the one pillar lower diffusion layer 9 and the pillar upper diffusion layers 16 are connected to the first metal wire 33. Hence, if one unit transistor goes out of order, the amount of the current of “4” or more and less than “5” flows in the remaining four unit transistors depending on capacity of each transistor because the current uniformly flows in the respective unit transistors. A potential of the pillar lower diffusion layer 9 normally becomes about half of the drain voltage. If one unit transistor connected to the drain goes out of order, the potential of the pillar lower diffusion layer 9 becomes less than the half of the drain voltage, the current flowing in the normal unit transistors increases, and it is therefore possible to flow the current more than the amount of “4”. In a case where the unit transistor does not reach a fault but has some worse characteristic, degradation of the characteristic is minuscule because the characteristic is compensated by other unit transistors. In other words, unevenness in the characteristic becomes small as compared with a case where the pillar lower diffusion layers 9 are provided in the different active regions every unit transistor and are connected in parallel with each other.

(3) Inasmuch as the channel portions of the unit transistors constituting the serial/parallel transistor are configured by the plurality of silicon pillars, it is possible to keep the thickness of one silicon pillar (a size in cross section cut at a surface in parallel with the silicon substrate 1) small up to a size allowing a full depletion. It is therefore possible to obtain an excellent S value (sub-threshold coefficient) and a large drain current in a state where the characteristic of a full depletion type high-breakdown voltage transistor is maintained.

(4) Inasmuch as the plurality of silicon pillars included in one unit transistor group are connected to one pillar lower diffusion layer 9 so that the respective silicon pillars (the first through the fifth silicon pillars 5A₁ to 5A₅ or the sixth through the tenth silicon pillars 5B₁ to 5B₅) are shared with one pillar lower diffusion layer 9, it is possible to minimize a footprint of the unit transistor group.

(5) Inasmuch as the plurality of silicon pillars included in the plurality of unit transistor groups are connected to one pillar lower diffusion layer 9 so that the respective silicon pillars (the first through the fifth silicon pillars 5A₁ to 5A₅ and the sixth through the tenth silicon pillars 5B₁ to 5B₅) are shared with one pillar lower diffusion layer 9, it is possible to minimize a footprint of the unit transistor group.

### Example 2

Referring now to Figures, a second example of this invention will be described. The second example relates to a semiconductor device configured so that a first serial-parallel transistor configured to share with a pillar lower diffusion layer in one active region described in the first example is also provided to a different active region sandwiching a STI area therebetween to make a second serial-parallel transistor, and the first serial-parallel transistor and the second serial-parallel transistor are connected in series via a wire.

Figures used in describing the second example are basically similar to those of the first example. In addition, the description of contents having in common to the first example is omitted and only differences in the second example will be described.

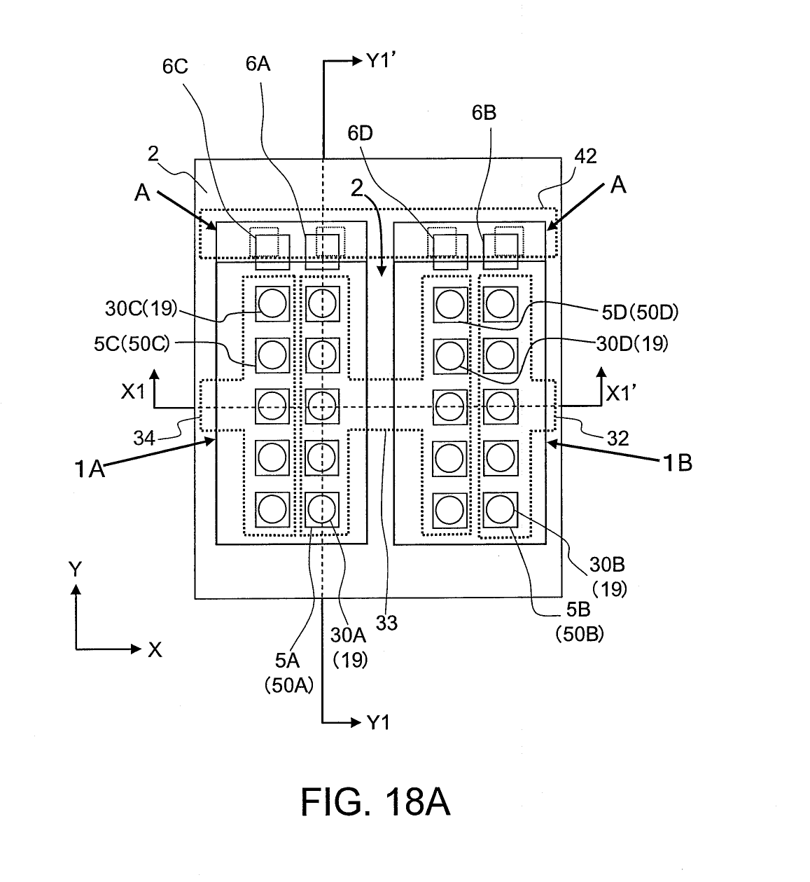

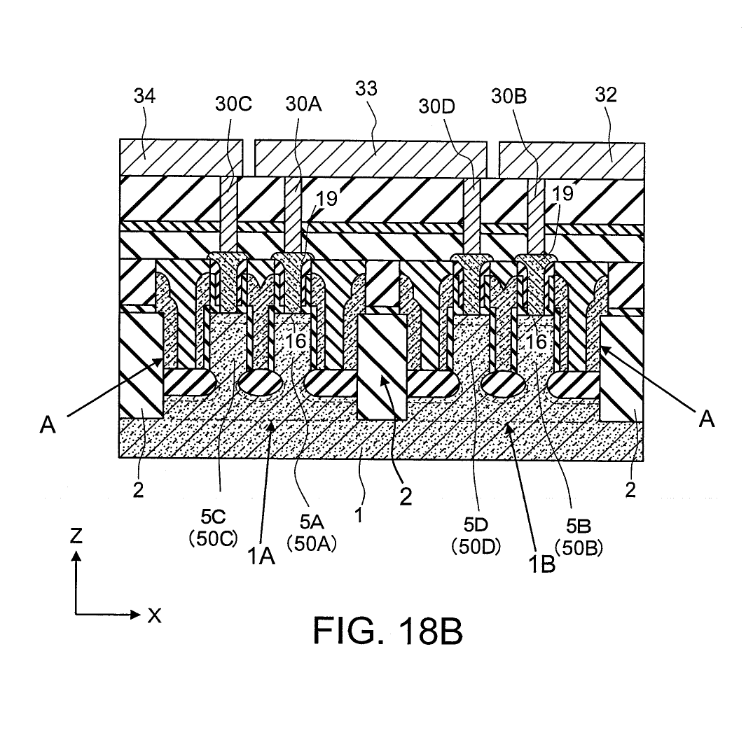

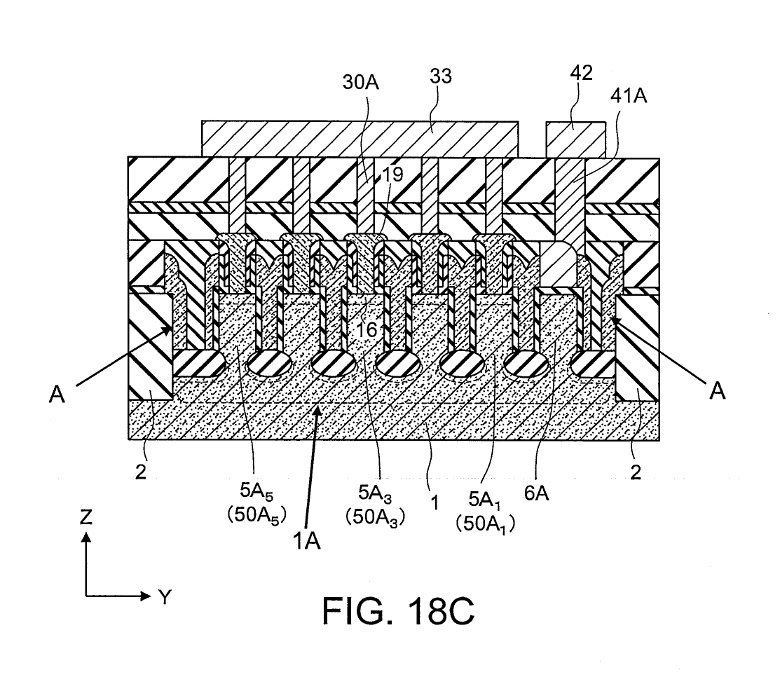

FIGS. 18A, 18B, and 18C are perspective views showing a configuration of the semiconductor device according to the second example of this present invention. FIG. 18A is a plan view of the semiconductor device according to the second example. FIG. 18B is a cross-sectional view taken on line X1-X1′ of FIG. 18A and FIG. 18C is a cross-sectional view taken on line Y1-Y1′ of FIG. 18A. However, in FIG. 18A, in order to define a layout condition of components, interlayer insulating films and wires positioned on contact plugs are put into a transmittance state and only in outline thereof is described.

Referring now to FIG. 18A, this example is provided with two active regions consisting of a first active region 1A and a second active region 1B which are surrounded with the STI 2. The first active region 1A and the second active region 1B are configured so that each has a rectangular shape having a longitudinal direction in the Y direction and they are adjacent by sandwiching the STI 2 therebetween. That is, the first active region 1A and the second active region 1B are isolated and separated by the STI 2. Each of the first and the second active regions 1A and 1B is provided with ten silicon pillars each having a rectangular shape in the XY plane. Specifically, the first active region 1A is provided with a first silicon pillar group 5A and a third silicon pillar group 5C each of which extends in the Y direction. Similarly, the second active region 1B is provided with a second silicon pillar group 5B and a fourth silicon pillar group 5D each of which extends in the Y direction.

The first silicon pillar group 5A constitutes a first unit transistor group 50A, namely, a first vertical transistor while the third silicon pillar group 5C constitutes a third unit transistor group 50C, namely, a third vertical transistor. The first vertical transistor and the third vertical transistor constitute a first serial/parallel transistor as in the case of FIGS. 1A to 1D of the first example.

In addition, the second silicon pillar group 5B constitutes a second unit transistor group 50B, namely, a second vertical transistor while the fourth silicon pillar group 5D constitutes a fourth unit transistor group 50D, namely, a fourth vertical transistor. The second vertical transistor and the fourth vertical transistor constitute a second serial/parallel transistor as in the case of FIGS. 1A to 1D of the first example.

In each vertical transistor provided in each region shown in FIG. 18A, the corresponding dummy pillar 6 is provided at a position of one end portion of each vertical transistor in the extending direction (the Y direction). Inasmuch as others, such as an arrangement of each silicon pillar, an arrangement of each gate electrode, a configuration of the dummy pillar 6, or the like are similar to those of the first example, the description thereof is omitted.

The semiconductor device according to this example comprises the first serial/parallel transistor provided in the first active region 1A and the second serial/parallel transistor provided in the second active region 1B that are connected in series by sandwiching the STI 2 therebetween. That is, the semiconductor device according this example is configured so that the first vertical transistor (the first unit transistor group 50A) constituting the first serial/parallel transistor and the fourth vertical transistor (the fourth unit transistor group 50D) constituting the second serial/parallel transistor are connected via the first metal wire 33. More specifically, the semiconductor device according to this example comprises, as main components, the third metal wire 32, the second vertical transistor (the second unit transistor group 50B) connected to the third metal wire 32, the fourth vertical transistor (the fourth unit transistor group 50D) connected to the second vertical via the shared pillar lower diffusion layer 9, the first vertical transistor (the first unit transistor group 50A) connected to the fourth vertical transistor via the shared first metal wire 33 extending over the STI 2, the third vertical transistor (the third unit transistor group 50C) connected to the first vertical transistor via the shared pillar diffusion layer 9, and the second metal wire 34 connected to the third vertical transistor.

Referring now to FIGS. 18B and 18C, the first active region 1A and the second active region 1B surrounded with the STI 2 are provided with ten silicon pillars in a standing manner, respectively, as in the case of the first example. The third metal wire 32 is connected via the silicon plugs 19 and second contact plugs 30B to the pillar upper diffusion layers 16 of the respective silicon pillars constituting the second silicon pillar group 5B of the second active region 1B. The first metal wire 33 has one end portion which is connected via the silicon plugs 19 and fourth contact plugs 30D to the pillar upper diffusion layers 16 of the respective silicon pillars constituting the fourth silicon pillar group 5D of the second active region 1B.

The first metal wire 33 has another end portion which is connected via the silicon plugs 19 and first metal contact plugs 30A to the pillar upper diffusion layers 16 of the respective silicon pillars constituting the first silicon pillar group 5A of the first active region 1A.

The second metal wire 34 is connected via the silicon plugs 19 and third contact plugs 30C to the pillar upper diffusion layers 16 of the respective silicon pillars constituting the third silicon pillar group 5C of the first active region 1A.

Immediately above the respective silicon pillars constituting the first silicon pillar group 5A, the silicon plugs 19, the first metal contact plugs 30A, and the first metal wire 33 are disposed. Immediately above the respective silicon pillars constituting the fourth silicon pillar group 5D, the silicon plugs 19, the fourth metal contact plugs 30D, and the first metal wire 33 are disposed.

With this structure, the first metal wire 33 serves as a wire for connecting in series the pillar upper diffusion layers 16 of the five unit transistors constituting the first unit transistor group 50A in the first active region 1A with the pillar upper diffusion layers 16 of the five unit transistors constituting the fourth unit transistor group 50D in the second active region 1B. In addition, the first metal wire 33 acts as a wire for connecting in parallel with the five unit transistors constituting the first unit transistor group 50A of the first active region 1A and also acts as a wire for connecting in parallel with the five unit transistors constituting the fourth unit transistor group 50D of the second active region 1B.

The semiconductor device may be configured so that the interval between the adjacent silicon pillar groups is separated in each active region in the case of FIGS. 2A and 2B serving as the modified example of the first example to isolate and separate the corresponding gate electrodes.

In accordance with the semiconductor device of the second example described above, the following advantages are obtained.

(1) Inasmuch as the semiconductor device is configured so that the first and the second serial/parallel transistors, each of which is described in the first example, are disposed in the different active regions and that the first and the second serial/parallel transistors are connected in series by the wire 33, it is possible to provide a further high-breakdown voltage transistor with maintaining the effects of the serial-parallel transistor described in the first example.

(2) According to the semiconductor device of this example, inasmuch as the first and the second serial/parallel transistors are disposed in the first and the second active regions via the STI 2, respectively, and the first and the second serial/parallel transistors are connected in series via the wire, it is not necessary for the first active region and the second active region to be adjacent in the same direction, and it is therefore possible to arbitrarily select the arrangement of the respective active regions.

In addition, the second example makes a modification to the first example such as an addition of the third and the second silicon pillar groups 5C and 5D, an addition of the third and the fourth dummy pillars 6C and 6D, an addition of the third and the fourth metal contact plugs 30C and 30D, an addition of the third and the fourth gate metal contact plugs 41C and 41D, an addition of the third metal wire 32, and a shape modification of the first and the second metal wires 33 and 34, any of them can be simultaneously formed with the components of the first example. As a result, the description of FIGS. 5 to 17 should be referred to as regards a method of manufacturing the semiconductor device according to the second example.

### Example 3

Referring now to Figures, a third example of this invention will be described. The third example relates to a semiconductor transistor configured so that the first and the second vertical transistors constituting the first serial/parallel transistor where the pillar lower diffusion layer is shared in one active region described in the first example are disposed in different active regions sandwiching the STI area therebetween to connect them in series via a wire. That is, the semiconductor device according to the third example is configured so that the first and the second pillar lower diffusion layers are shared to make the two pillar lower diffusion layers at the same potential by connecting the first pillar lower diffusion layer of the first vertical transistor disposed in the first active region with the second pillar lower diffusion layer of the second vertical transistor disposed in the second active region by the wire. In this event, the semiconductor device according to the third example is configured to an equivalent circuit which is similar to that shown in FIG. 3 of the first example.

Individual components of the third example are basically similar to those of the first example. In addition, the description of contents having in common to the first example is omitted and only differences in the third example will be described.

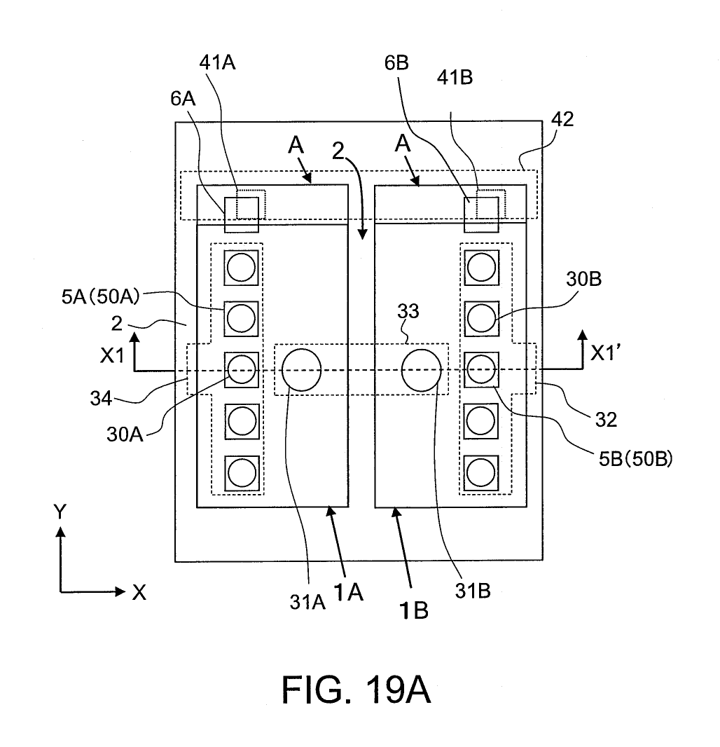

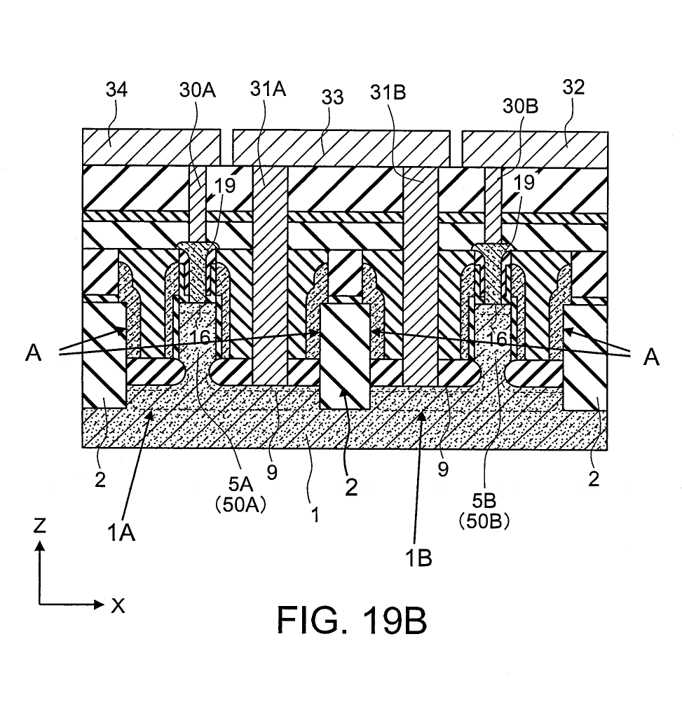

FIGS. 19A and 19B are perspective views showing a configuration of the semiconductor device according to the third example of this present invention. FIG. 19A is a plan view of the semiconductor device according to the third example. FIG. 19B is a cross-sectional view taken on line X1-X1′ of FIG. 19A. However, in FIG. 19A, in order to define a layout condition of components, interlayer insulating films and wires positioned on contact plugs are put into a transmittance state and only in outline thereof is described.

This example is provided with two active regions consisting of a first active region 1A and a second active region 1B which are surrounded with the STI 2. The first active region 1A and the second active region 1B are configured so that each has a rectangular shape having a longitudinal direction in the Y direction and that they are adjacent to each other by sandwiching the STI 2 therebetween. Each of the first and the second active regions 1A and 1B is provided with one silicon pillar groups (5A or 5B) comprising the five silicon pillars each of which has a rectangular shale in the XY plane, and one dummy pillar (6A or 6B), and one metal contact plug (31A or 31B).

Disposed in the first active region 1A, the first silicon pillar group 5A extending in the Y direction constitutes the first unit transistor group 50A, namely, the first vertical transistor. The first metal contact plug 31A is disposed at a position adjacent in the X direction of a side opposed to the second active region 1B in composition with the first vertical transistor.

On the other hand, disposed in the second active region 1B, the second silicon pillar group 5B extending in the Y direction constitutes the second unit transistor group 50B, namely, the second vertical transistor. The second metal contact plug 31B is disposed at a position adjacent in the X direction and at a side opposed to the first metal contact plug 31A. Accordingly, the semiconductor device according to third example is configured so that the first metal contact plug 31A disposed in the first active region 1A and the second metal contact plug 31B disposed in the second active region 1B are opposed to each other. Inasmuch as an arrangement of each silicon pillar, an arrangement of each gate electrode, a configuration of the dummy pillar 6, or the like are similar to those of the first example, the description thereof is omitted.

The third metal wire 32 is connected via the second metal contact plugs 30B and the silicon plugs 19 to the pillar upper diffusion layers 16 constituting the second unit transistor group 50B of the second active region 1B.

The first metal wire 33 has one end portion which is connected to a top face of the first metal contact plug 31A and which is connected via the first metal contact plug 31A to the pillar lower diffusion layer 9 constituting the first unit transistor group 50A of the first active region 1A. In addition, the first metal wire 33 has another end portion which is connected to a top face of the second metal contact plug 31B and which is connected via the second metal contact plug 31B to the pillar lower diffusion layer 9 constituting the second unit transistor group 50B of the second active region 1B. The semiconductor device according to this example is configured so that the pillar lower diffusion layer 9 formed in the first active region 1A and the pillar lower diffusion layer 9 formed in the second region 1B are connected by the first metal wire 33. Accordingly, the semiconductor device according to the third example is configured so that the pillar lower diffusion layer of the first vertical transistor disposed in the first active region 1A and the pillar lower diffusion layer of the second vertical transistor disposed in the second active region 1B are at the same potential to be shared.

The second metal wire 34 is connected via the first metal contact plugs 30A and the silicon plugs 19 to the pillar upper diffusion layers 16 constituting the first unit transistor group 50A of the first active region 1A.

The first metal wire 33 extends in an arrangement direction of the first active region 1A and the second active region 1B and is disposed so as to extend over the first active region 1A and the second active region 1B via the STI 2.

The semiconductor device according to this example is configured so that the first vertical transistor disposed in the first active region 1A and the second vertical transistor disposed in the second active region 1B are disposed so as to sandwich the STI 1 therebetween and the pillar lower diffusion layers 9 disposed in the respective regions are connected in series by the first metal wire 33 via the metal contact plugs 31A and 31B. More specifically, the semiconductor device according to this example comprises, as main components, the third metal wire 32, the second vertical transistor of the second active regions 1B that is connected to the third metal wire 32, the second metal contact plug 31B connected to the pillar lower diffusion layer 9 constituting the second vertical transistor, the first metal wire 33 which is connected to the second metal contact plug 31B and which is disposed so as to extend over the first active region 1A and the second active region 1B via the STI 2, the first metal contact plug 31A which is connected to the first metal wire 33 and which is connected to the pillar lower diffusion layer 9 of the first active region 1A, the first vertical transistor connected to the first metal contact plug 31A, and the second metal wire 34 connected to the first vertical transistor.

According to the semiconductor device of the third example described above, inasmuch as it is configured so that the pillar lower diffused layer constituting the first vertical transistor disposed in the first active region 1A and the pillar lower diffusion layer constituting the second vertical transistor disposed in the second active region 1B are connected by the metal wire 33 via the metal contact plugs 31A and 31B, the pillar lower diffusion layer of the first active region 1A and the pillar lower diffusion layer of the second active region 1B are at the same potential, it is therefore possible to make a configuration equivalent to that where the two vertical transistors are disposed so as to share the pillar lower diffusion layer in one region and are connected in series to each other, as described in the first example. It is therefore possible to obtain effects which are similar to those in the first example. Inasmuch as one vertical transistor is disposed in one region in this example, it is possible to provide the serial/parallel transistor which is arbitrarily disposed in a state where a limitation of layout is reduced.

Although description has been made so that both of the first active region 1A and the second active region 1B are disposed to make a rectangular shape in this example, this invention is not limited thereto. If the metal contact plugs are disposed in active regions likened to arrangements of the vertical transistors, the dumpy pillars, and the metal contact plugs, for example, in protruded portions formed in convex areas, it is possible to further reduce a footprint area of the active regions, and it is advantageous to miniaturization of the semiconductor device. Although FIG. 19A shows an example in which the metal contact plug is disposed at a substantial center portion in the Y direction within the active region, this invention is not limited thereto, the metal contact plug may be disposed at an arbitrary position in the Y direction.

The semiconductor device according to the third example can be manufactured in accordance with a method of manufacturing the semiconductor device according to the first example.

Although preferred examples of the present invention have been explained, the present invention is not limited to these examples. Various modifications can be made so long as they not depart from the gist of the present invention and they are included in a range of the present invention.

What is claimed is:

1. A semiconductor device comprising:
a high-breakdown voltage transistor including at least first and second vertical transistors which are connected in series,
wherein the first vertical transistor comprises a first unit transistor group comprising a plurality of unit transistors each of which includes a semiconductor pillar,
wherein the second vertical transistor comprises a second unit transistor group comprising a plurality of unit transistors each of which includes a semiconductor pillar,
wherein the plurality of unit transistors constituting the first and the second unit transistor groups have pillar lower diffusion layers which are shared.

2. The semiconductor device as claimed in claim 1, wherein the first and the second vertical transistors are disposed in an active region.

3. The semiconductor device as claimed in claim 2,
wherein the plurality of unit transistors constituting the first unit transistor group comprise first pillar upper diffusion layers which are connected in parallel to each other,
wherein the plurality of unit transistors constituting the second unit transistor group comprise second pillar upper diffusion layers which are connected in parallel to each other.

4. The semiconductor device as claimed in claim 3,
wherein the plurality of unit transistors constituting the first unit transistor group comprise:
a first semiconductor pillar group comprising a plurality of semiconductor pillars;
the pillar lower diffusion layer disposed in lower end portions of the plurality of semiconductor pillars constituting the first semiconductor pillar group; and
the first pillar upper diffusion layers disposed in respective upper end portions of the plurality of semiconductor pillars constituting the first semiconductor pillar group,
wherein the plurality of unit transistors constituting the second unit transistor group comprise:
a second semiconductor pillar group comprising a plurality of semiconductor pillars;
the pillar lower diffusion layer disposed in lower end portions of the plurality of semiconductor pillars constituting the second semiconductor pillar group; and
the second pillar upper diffusion layers disposed in respective upper end portions of the plurality of semiconductor pillars constituting the second semiconductor pillar group.

5. The semiconductor device as claimed in claim 2,
wherein the first unit transistor group comprises:
a first semiconductor pillar group comprising a plurality of semiconductor pillars which are formed in a predetermined direction with a space therebetween;
first gate insulating films which are provided on respective outer circumferential surfaces of the plurality of semiconductor pillars constituting the first semiconductor pillar group; and
first gate electrodes which are formed over side faces of the plurality of semiconductor pillars constituting the first semiconductor pillar group via the first gate insulating films so as to fill gaps between the plurality of semiconductor pillars constituting the first semiconductor pillar group,
wherein the second unit transistor group comprises:
a second semiconductor pillar group comprising a plurality of semiconductor pillars which are formed in the predetermined direction with a space therebetween;
second gate insulating films which are provided on respective outer circumferential surfaces of the plurality of semiconductor pillars constituting the second semiconductor pillar group; and
second gate electrode which are formed over side faces of the plurality of semiconductor pillars constituting the second semiconductor pillar group via the second gate insulating films so as to fill gaps between the plurality of semiconductor pillars constituting the second semiconductor pillar group.

6. The semiconductor device as claimed in claim 5, wherein the first gate electrodes and the second gate electrodes are electrically connected to each other.

7. The semiconductor device as claimed in claim 5, wherein the first gate electrodes and the second gate electrodes are electrically separated from each other.

8. The semiconductor device as claimed in claim 3, wherein the first and the second vertical transistors constitute a serial/parallel transistor, a plurality of serial/parallel transistors being disposed so as to connect in series.

9. The semiconductor device as claimed in claim 1, wherein the first and the second vertical transistors are disposed in first and second active regions, respectively, which are adjacent to each other in a state where an element separation area is sandwiched therebetween,
wherein the plurality of unit transistors constituting the first unit transistor group have first pillar lower diffusion layers which are shared,
wherein the plurality of unit transistors constituting the second unit transistor group have second pillar lower diffusion layers which are shared.

10. The semiconductor device as claimed in claim 9,
wherein the plurality of unit transistors constituting the first unit transistor group comprise first pillar upper diffusion layers which are connected in parallel to each other,
wherein the plurality of unit transistors constituting the second unit transistor group comprise second pillar upper diffusion layers which are connected in parallel to each other.

11. The semiconductor device as claimed in claim 9,
wherein the plurality of unit transistors constituting the first unit transistor group comprise:
a first semiconductor pillar group comprising a plurality of semiconductor pillars;
the pillar lower diffusion layer disposed in lower end portions of the plurality of semiconductor pillars constituting the first semiconductor pillar group; and
the first pillar upper diffusion layers disposed in respective upper end portions of the plurality of semiconductor pillars constituting the first semiconductor pillar group,
wherein the plurality of unit transistors constituting the second unit transistor group comprise:
a second semiconductor pillar group comprising a plurality of semiconductor pillars;
the pillar lower diffusion layer disposed in lower end portions of the plurality of semiconductor pillars constituting the second semiconductor pillar group; and
the second pillar upper diffusion layers disposed in respective upper end portions of the plurality of semiconductor pillars constituting the second semiconductor pillar group.

12. The semiconductor device as claimed in claim 9, wherein the first pillar lower diffusion layers are connected in series to the second pillar lower diffusion layers.

13. The semiconductor device as claimed in claim 9,
wherein the first unit transistor group comprises:
a first semiconductor pillar group comprising a plurality of semiconductor pillars which are formed in a predetermined direction with a space therebetween;
first gate insulating films which are provided on respective outer circumferential surfaces of the plurality of semiconductor pillars constituting the first semiconductor pillar group; and
first gate electrodes which are formed over side faces of the plurality of semiconductor pillars constituting the first semiconductor pillar group via the first gate insulating films so as to fill gaps between the plurality of semiconductor pillars constituting the first semiconductor pillar group,
wherein the second unit transistor group comprises:
a second semiconductor pillar group comprising a plurality of semiconductor pillars which are formed in the predetermined direction with a space therebetween;
second gate insulating films which are provided on respective outer circumferential surfaces of the plurality of semiconductor pillars constituting the second semiconductor pillar group; and
second gate electrode which are formed over side faces of the plurality of semiconductor pillars constituting the second semiconductor pillar group via the second gate insulating films so as to fill gaps between the plurality of semiconductor pillars constituting the second semiconductor pillar group.

14. The semiconductor device as claimed in claim 9,
wherein the first vertical transistor further comprises a third unit transistor group which is disposed adjacent to the first unit transistor group and which comprises a plurality of unit transistors each including a semiconductor pillar, the plurality of unit transistors constituting the first and the third unit transistor groups having first and third pillar lower diffusion layers, respectively, each of which are shared,
wherein the second vertical transistor further comprises a fourth unit transistor group which is disposed adjacent to the second unit transistor group and which comprises a plurality of unit transistors each including a semiconductor pillar, the plurality of unit transistors constituting the second and the fourth unit transistor groups having second and fourth pillar lower diffusion layers, respectively, each of which are shared.

15. The semiconductor device as claimed in claim 14,
wherein the plurality of unit transistors constituting the first unit transistor group comprise first pillar upper diffusion layers which are connected in parallel to each other,
wherein the plurality of unit transistors constituting the second unit transistor group comprise second pillar upper diffusion layers which are connected in parallel to each other,
wherein the plurality of unit transistors constituting the third unit transistor group comprise third pillar upper diffusion layers which are connected in parallel to each other,
wherein the plurality of unit transistors constituting the fourth unit transistor group comprise fourth pillar upper diffusion layers which are connected in parallel to each other.

16. The semiconductor device as claimed in claim 15,
wherein the plurality of unit transistors constituting the first unit transistor group comprise:
a first semiconductor pillar group comprising a plurality of semiconductor pillars;
the first pillar lower diffusion layer disposed in lower end portions of the plurality of semiconductor pillars constituting the first semiconductor pillar group; and
the first pillar upper diffusion layers disposed in respective upper end portions of the plurality of semiconductor pillars constituting the first semiconductor pillar group,
wherein the plurality of unit transistors constituting the second unit transistor group comprise:
a second semiconductor pillar group comprising a plurality of semiconductor pillars;
the second pillar lower diffusion layer disposed in lower end portions of the plurality of semiconductor pillars constituting the second semiconductor pillar group; and
the second pillar upper diffusion layers disposed in respective upper end portions of the plurality of semiconductor pillars constituting the second semiconductor pillar group,
wherein the plurality of unit transistors constituting the third unit transistor group comprise:
a third semiconductor pillar group comprising a plurality of semiconductor pillars;
the third pillar lower diffusion layer disposed in lower end portions of the plurality of semiconductor pillars constituting the third semiconductor pillar group; and
the third pillar upper diffusion layers disposed in respective upper end portions of the plurality of semiconductor pillars constituting the first semiconductor pillar group,
wherein the plurality of unit transistors constituting the fourth unit transistor group comprise:
a fourth semiconductor pillar group comprising a plurality of semiconductor pillars;
the fourth pillar lower diffusion layer disposed in lower end portions of the plurality of semiconductor pillars constituting the fourth semiconductor pillar group; and
the fourth pillar upper diffusion layers disposed in respective upper end portions of the plurality of semiconductor pillars constituting the fourth semiconductor pillar group.

17. The semiconductor device as claimed in claim 15, wherein the first pillar upper diffusion layers are connected in series to the fourth pillar upper diffusion layers.

18. The semiconductor device as claimed in claim 14,
wherein the first unit transistor group comprises:
a first semiconductor pillar group comprising a plurality of semiconductor pillars which are formed in a predetermined direction with a space therebetween;
first gate insulating films which are provided on respective outer circumferential surfaces of the plurality of semiconductor pillars constituting the first semiconductor pillar group; and
first gate electrodes which are formed over side faces of the plurality of semiconductor pillars constituting the first semiconductor pillar group via the first gate insulating films so as to fill gaps between the plurality of semiconductor pillars constituting the first semiconductor pillar group,
wherein the second unit transistor group comprises:
a second semiconductor pillar group comprising a plurality of semiconductor pillars which are formed in the predetermined direction with a space therebetween;
second gate insulating films which are provided on respective outer circumferential surfaces of the plurality of semiconductor pillars constituting the second semiconductor pillar group; and
second gate electrode which are formed over side faces of the plurality of semiconductor pillars constituting the second semiconductor pillar group via the second gate insulating films so as to fill gaps between the plurality of semiconductor pillars constituting the second semiconductor pillar group,
wherein the third unit transistor group comprises:
a third semiconductor pillar group comprising a plurality of semiconductor pillars which are formed in the predetermined direction with a space therebetween;
third gate insulating films which are provided on respective outer circumferential surfaces of the plurality of semiconductor pillars constituting the third semiconductor pillar group; and
third gate electrodes which are formed over side faces of the plurality of semiconductor pillars constituting the third semiconductor pillar group via the third gate insulating films so as to fill gaps between the plurality of semiconductor pillars constituting the third semiconductor pillar group,
wherein the fourth unit transistor group comprises:
a fourth semiconductor pillar group comprising a plurality of semiconductor pillars which are formed in the predetermined direction with a space therebetween;
fourth gate insulating films which are provided on respective outer circumferential surfaces of the plurality of semiconductor pillars constituting the fourth semiconductor pillar group; and
fourth gate electrode which are formed over side faces of the plurality of semiconductor pillars constituting the fourth semiconductor pillar group via the fourth gate insulating films so as to fill gaps between the plurality of semiconductor pillars constituting the fourth semiconductor pillar group.

19. The semiconductor device as claimed in claim 18,
wherein the first gate electrodes and the third gate electrodes are commonly connected to each other so as to fill gaps between the plurality of semiconductor pillars constituting the first and the third semiconductor pillar groups,
wherein the second gate electrodes and the fourth gate electrodes are commonly connected to each other so as to fill gaps between the plurality of semiconductor pillars constituting the second and the fourth semiconductor pillar groups.

20. The semiconductor device as claimed in claim 18, wherein the first gate electrodes, the second gate electrodes, the third gate electrodes, and the fourth gate electrodes are electrically connected to each other.
